(19) United States
(12) Patent Application Publication
(10) Pub. No.: US 2025/0234489 A1
(43) Pub. Date: Jul. 17, 2025

(54) DUAL-PHASE SELECTIVELY VAPOR-PERMEABLE MEMBRANE HEAT SINKS AND SERVER RACK COOLING SYSTEMS INTEGRATING THE SAME

(71) Applicant: UNIVERSITY OF FLORIDA RESEARCH FOUNDATION, INCORPORATED, Gainesville, FL (US)

(72) Inventor: Saeed Moghaddam, Gainesville, FL (US)

(21) Appl. No.: 19/012,419

(22) Filed: Jan. 7, 2025

Related U.S. Application Data
(60) Provisional application No. 63/619,996, filed on Jan. 11, 2024.

(51) Int. Cl. H05K 7/20

(52) U.S. Cl. CPC H05K 7/20327; H05K 7/20318; H05K 7/20381; H05K 7/20809

(57) ABSTRACT

Disclosed are dual-phase membrane heat sinks reaching unprecedented heat transfer coefficient and waste heat temperature recovery levels enabling, e.g., rejection of microchips heat to ambient, eliminating the need for chillers, direct waste heat utilization for buildings and industrial use, powering heat-driven chillers for cooling facilities, etc. Membranes function as mass controller, permitting entry of liquid in equilibrium with an evaporated amount fluxed across membranes, eliminating the need for flow control equipment. Bubbles discharge through membranes drastically reduces heat sink pressure drop enabling operation under hydrostatic pressure. Microchip thermal management array systems can include condenser heat exchanger(s) in fluidic communication with membrane heat sinks. Heat exchanger(s) can receive vapor volume of heat exchange fluid, expose the vapor volume of heat exchange fluid to a data center primary cooling loop to condense heat exchange fluid, and communicate only a liquid volume of the heat exchange fluid out of the condenser heat exchanger(s).

### CROSS-REFERENCE TO RELATED APPLICATIONS

The present application claims the benefit of priority under 35 U.S.C. § 120 to U.S. Provisional Patent Application Ser. No. 63/619,996, filed Jan. 11, 2024 and entitled “Method of Implementing Membrane Heat Sinks in Computer Servers Rack,” the entire disclosure of which is hereby incorporated herein by reference in its entirety for all purposes.

The present disclosure is also related to the subject matter disclosed in U.S. Provisional Patent Application Ser. No. 63/627,182, filed Jan. 31, 2024 and entitled “Manufacturing and Direct Die Attachment of Membrane Heat Sinks,” the entire disclosure of which is hereby incorporated herein by reference in its entirety for all purposes. The present disclosure is further related to the subject matter disclosed in U.S. Non-Provisional patent application Ser. No. 16/598,176, filed Oct. 10, 2019 and entitled “Hierarchical Hydrophilic/Hydrophobic Micro/Nanostructures for Pushing the Limits of Critical Heat Flux,” which is a continuation of U.S. Non-Provisional patent application Ser. No. 15/185,766, filed Jun. 17, 2016 and entitled “Hierarchical Hydrophilic/Hydrophobic Micro/Nanostructures for Pushing the Limits of Critical Heat Flux,” which is a continuation-in-part of International Patent Application Serial No. PCT/US2014/070903, filed Dec. 17, 2014, which claims priority to U.S. Provisional Application Ser. No. 61/917,177, filed Dec. 17, 2013, the entire disclosures of each of which are hereby incorporated herein by reference in their entireties for all purposes.

### STATEMENT OF GOVERNMENT SUPPORT

This invention was made with government support under DE-AR-0001756, awarded by US DEPT OF ENERGY ADVANCED RESEARCH PROJECTS AGENCY. The government has certain rights in the invention.

### FIELD

The present disclosure relates, generally, to membrane heat sinks, and in particular to dual-phase membrane heat sinks configured for use in cooling collocated computing devices.

### BACKGROUND

As data centers and server facilities continue to evolve, the demand for efficient heat dissipation mechanisms becomes increasingly critical, to both enable higher compute capability and mitigate the rapidly rising electricity demand for cooling. High-performance computing (HPC) devices generate substantial heat during operation, necessitating innovative solutions to remove this heat effectively. Existing systems rely on air or single-phase liquid cooling. However, rapid advancements of electronics, particularly AI microchips, demands that temperature of the liquid delivered to the microchips be lowered, resulting in greater chiller systems energy consumption.

Continuous advancement in microchips technology, driven by rapidly rising need for compute power is surpassing the capability of single-phase liquid heat sinks. As a result, introduction of innovative thermal management methods is desired to address demands of future electronic devices. Phase change heat sinks wherein boiling of a liquid is carried out has the ability to dissipate large quantities of heat from a microchip since it relies on the liquid latent heat of vaporization. Hence, cooling with phase change process can take place at a relatively small temperature difference between the microchip and the boiling liquid. As such, phase change heat transfer is considered the next step in advancing the data center cooling technology, and extensive research in being conducted to achieve performance levels exceeding those of the single-phase heat sinks and to address operational issues associated with a phase-change system.

Research on flow boiling in microchannel heat sinks has focused on enhancing heat transfer while reducing pressure drop and flow instabilities. In a conventional microchannel, liquid enters the channel while both liquid and vapor exit as a mixture. Heat transfer coefficient is a function of flow regime within the channel. There are three prominent flow regimes in microchannels including: 1) bubbly flow in which discrete bubbles are dispersed within the liquid, 2) elongated bubbles where in bubbles grow large enough to occupy the channel cross section, and 3) annular flow in which a thin liquid layer flows with a vapor core along the channel length. Efforts on heat transfer enhancement are focused on disruption of the thermal boundary layer and evaporation of the thin liquid layers formed on the microchannel wall surfaces.

Flow instabilities are complex and could greatly diminish microchannel heat sinks' performance, resulting in significant reduction in their cooling capacity. Four instability mechanisms relevant to the present investigation are the Rapid Bubble Growth (RBG), Ledinegg, Parallel Channel Flow (PCF), and the Critical Heat Flux (CHF) condition. These mechanisms are coupled. For instance, flow oscillations due to RBG instability can cause CHF or can trigger the PCF instability. RBG arises when bubbles grow explosively pushing the liquid upstream and into neighboring channels. Various techniques have been pursued to avoid high pressure drops or pressure fluctuations. These techniques include artificial nucleation sites, inlet restrictors, different inlet/outlet configurations, and various channel geometries.

Although improvements in performance characteristics of phase-change heat sinks have been extensively pursued, a breakthrough that could address shortcomings of phase change heat sinks, in relation to implementation in a computer server rack has not emerged. Regardless of whether individual heat sinks experience instability or not, development of a system consisting of numerous heat sinks within a rack operating reliably under highly dynamic conditions (due to continuous changes in processors power i.e., heat sink heat input) has been the primary challenge. This challenge arises from the fact that the pressure drop of the phase-change heat sinks is strongly affected by rapid growth of bubbles and the volume of vapor generated within the heat sink. Consequently, the heat sink pressure drop is a function of the microchip power. In a system with many heat sinks, this inherent characteristic of conventional heat sinks results in flow maldistribution, requiring flow control equipment to balance liquid delivery to servers and individual heat sinks based on their thermal load.

As such, there remains a great need for heat sinks that can handle high heat loads in massively parallel systems such as a computer server rack operating at high heat transfer coefficients, high vapor exit quality, and minimal pumping power requirement.

### BRIEF SUMMARY

Embodiments described herein are directed to heat sinks that have a liquid fluid entrance but a vapor fluid exit, where the vapor quality is 100%. The heat sink employs a hydrophobic porous membrane through which vapor readily passes but liquid cannot. As a growing bubble touches the membrane, the liquid-vapor contact line formed between the bubble and membrane recedes exerting a net force on the bubble pulling it away from the hot surface. This phenomenon fundamentally changes the physics of fluid flow near the surface since removing bubbles allows the liquid to rapidly rewet and cool the surface, resulting in major increase in the rate of heat transfer and maintaining a low surface temperature.

In the systems and devices of the current disclosure, bubble density is on the order of 1,000 times lower than the liquid. Hence, vaporization of a small amount of liquid results in generation of a bubble 1,000 times larger in volume. The membrane discharges bubbles from the liquid pool immediately as they form hence preventing high fluid velocities and associated excessive pressure drop within the liquid pool. Hence, the heat sink has substantially lower pressure drop relative to conventional heat sinks.

The device uses trenches to evenly supply coolant liquid to finned microstructured regions, which increase the heat transfer area and enhance liquid wickability. This design facilitates evaporation and ensures vapor exits to a condenser. The liquid introduction rate is balanced with vapor exit, enabling effective operation across a wide range of heat loads. The membrane retains liquid within the fins, ensuring full evaporation before additional liquid enters. By leveraging phase change over predefined surface structures, the evaporated liquid exits directly from above the fins, preventing pressure buildup and bubble kickback, thereby promoting efficient cooling and mitigating flow instabilities.

Described herein are membrane-based heat sinks and membrane-based heat exchangers, as well as devices and systems, such as servers, server racks, server arrays, or data centers, configured for using the same to cool collocated computing devices therein/thereof. For example, a system or device can be or comprise a membrane heat sink configured to absorb excess heat emitted by a collocated computing device. In some embodiments, the membrane heat sink can comprise a liquid region comprising an inlet port configured to communicate a liquid phase heat exchange fluid into the liquid region. In some embodiments, the membrane heat sink can further comprise a vapor region comprising an outlet port configured to communicate a vapor phase heat exchange fluid out of the membrane heat sink. In some embodiments, the membrane heat sink can further comprise a vapor-permeable membrane disposed between the liquid region and the vapor region. In some embodiments, the vapor-permeable membrane is configured to allow communication therethrough of the vapor phase heat exchange fluid and disallow communication therethrough of the liquid phase heat exchange fluid. In some embodiments, a rate of communication of the vapor phase heat exchange fluid through the outlet port and out of the vapor region of the membrane heat sink is based upon a rate of communication of the vapor phase heat exchange fluid through the vapor-permeable membrane from the liquid region to the vapor region. In some embodiments, a rate of communication of the liquid phase heat exchange fluid through the inlet port and into the liquid region is based on the rate of communication of the vapor phase heat exchange fluid through vapor-permeable membrane from the liquid region to the vapor region. In some embodiments, the rate of communication of the vapor phase heat exchange fluid through the vapor-permeable membrane from the liquid region into the vapor region is based on a rate at which the liquid phase heat exchange fluid undergoes the phase change to the vapor phase heat exchange fluid. In some embodiments, the rate at which the liquid phase heat exchange fluid undergoes the phase change to the vapor phase heat exchange fluid is based upon a quantity of the excess heat absorbed by the liquid phase heat exchange fluid.

In some embodiments, the membrane heat sink is further configured, during a first time, to absorb a first quantity of excess heat emitted by the collocated computing device, causing the liquid phase heat exchange fluid in the liquid region to undergo a phase change to the vapor phase heat exchange fluid at a first rate. In some embodiments, the volume of the liquid phase heat exchange fluid that undergoes the phase change to the vapor phase heat exchange fluid during the first time is based upon a first quantity of the excess heat absorbed by the liquid phase heat exchange fluid during the first time. In some embodiments, the membrane heat sink is further configured, during a second time, to absorb a second quantity of excess heat emitted by the collocated computing device, causing the liquid phase heat exchange fluid in the liquid region to undergo the phase change to the vapor phase heat exchange fluid at a second rate. In some embodiments, the volume of the liquid phase heat exchange fluid that undergoes the phase change to the vapor phase heat exchange fluid during the second tie is based upon a second quantity of the excess heat absorbed by the liquid phase heat exchange fluid during the second time.

According to another embodiment, a membrane heat sink device can be provided that comprises a first membrane heat sink configured to be collocated during a time period with a first computing device emitting a first quantity of excess heat during the time period, the first membrane heat sink comprising a first liquid region and a first vapor region, the first liquid region being separated from the first vapor region by a first vapor-permeable membrane, the first liquid region comprising a first inlet configured to communicate a first volume of a liquid phase heat exchange fluid into the first liquid region during the time period. In some embodiments, the first membrane heat sink is configured to communicate a second quantity of excess heat from the first computing device into the first liquid region, the second quantity of excess heat being correlated with the first quantity of excess heat emitted from the first computing device during the time period. In some embodiments, the first volume of the liquid phase heat exchange fluid is configured to absorb the second quantity of excess heat communicated into the first liquid region during the time period such that at least a portion of the first volume of the liquid phase heat exchange fluid undergoes a phase change to a first volume of a vapor phase heat exchange fluid. In some embodiments, a quantity of the portion of the first volume of the liquid phase heat exchange fluid that undergoes the phase change is based on the second quantity of excess heat absorbed by the first volume of the liquid phase heat exchange fluid during the time period. In some embodiments, the first vapor-permeable membrane is configured to allow communication of the first portion of the vapor phase heat exchange fluid from the first liquid region, through the first vapor-permeable membrane, and into the first vapor region. In some embodiments, the first vapor region comprises a first outlet configured to communicate the first volume of the vapor phase heat exchange fluid out of the first vapor region of the first membrane heat sink during the time period. In some embodiments, the first volume of the vapor phase heat exchange fluid communicated out of the first vapor region of the first membrane heat sink via the first outlet during the time period controls the first volume of the liquid phase heat exchange fluid communicated into the first liquid region of the first membrane heat sink via the first inlet port during the time period.

In some embodiments, the membrane heat sink device can further comprise a second membrane heat sink configured to be collocated during the time period with a second computing device emitting a third quantity of excess heat during the time period, the second membrane heat sink comprising a second liquid region and a second vapor region, the second liquid region being separated from the second vapor region by a second vapor-permeable membrane, the second liquid region comprising a second inlet configured to communicate a second volume of the liquid phase heat exchange fluid into the second liquid region during the time period. In some embodiments, the second membrane heat sink is configured to communicate a fourth quantity of excess heat from the second computing device into the second liquid region, the fourth quantity of excess heat being correlated with the third quantity of excess heat emitted from the second computing device during the time period. In some embodiments, the second volume of the liquid phase heat exchange fluid is configured to absorb the fourth quantity of excess heat communicated into the second liquid region during the time period such that at least a portion of the second volume of the liquid phase heat exchange fluid undergoes the phase change to a second volume of the vapor phase heat exchange fluid. In some embodiments, a quantity of the portion of the second volume of the liquid phase heat exchange fluid that undergoes the phase change is based on the fourth quantity of excess heat absorbed by the second volume of the liquid phase heat exchange fluid during the time period. In some embodiments, the second vapor-permeable membrane is configured to allow communication of the second portion of the vapor phase heat exchange fluid from the second liquid region, through the second vapor-permeable membrane, and into the second vapor region. In some embodiments, the second vapor region comprises a second outlet configured to communicate the second volume of the vapor phase heat exchange fluid out of the second vapor region of the second membrane heat sink during the time period. In some embodiments, the second volume of the vapor phase heat exchange fluid communicated out of the second vapor region of the second membrane heat sink via the second outlet during the time period controls the second volume of the liquid phase heat exchange fluid communicated into the second liquid region of the second membrane heat sink via the second inlet port during the time period.

In some embodiments, the membrane heat sink device can further comprise a liquid phase heat exchange fluid reservoir configured to store a replenishing supply of the liquid phase heat exchange fluid, configured to communicate the first volume of the liquid phase heat exchange fluid into the first liquid region within the first membrane heat sink during the time period, and configured to communicate the second volume of the liquid phase heat exchange fluid into the second liquid region within the second membrane heat sink during the time period. In some embodiments, the membrane heat sink device can further comprise a vapor phase heat exchange fluid recovery unit configured to cause a second phase change of the first and second volumes of the vapor phase heat exchange fluid back to liquid phase heat exchange fluid. In some embodiments, the membrane heat sink device can further comprise a liquid phase heat exchange fluid distribution system in fluidic communication with the liquid phase heat exchange fluid reservoir, the first membrane heat sink, and the second membrane heat sink. In some embodiments, the liquid phase heat exchange fluid distribution system is configured to maintain the liquid phase heat exchange fluid within the liquid phase heat exchange fluid distribution system at a hydrostatic pressure within a predetermined range.

According to another embodiment, a system can be provided that comprises a first computing device emitting a first quantity of heat during a time period and a first membrane heat sink collocated with the first computing device, the first membrane heat sink comprising a first liquid region and a first vapor region, the first liquid region being separated from the first vapor region by a first vapor-permeable membrane, the first liquid region comprising a first inlet configured to communicate a first volume of a liquid phase heat exchange fluid into the first liquid region, wherein the first membrane heat sink is configured to communicate a second quantity of heat from the first computing device into the first liquid region, wherein the second quantity of heat is correlated with the first quantity of heat emitted from the first computing device during the time period, wherein the first volume of the liquid phase heat exchange fluid is configured to absorb the second quantity of heat communicated into the first liquid region during the time period such that at least a first portion of the first volume of the liquid phase heat exchange fluid undergoes a phase change to a first volume of a vapor phase heat exchange fluid, wherein a quantity of the first portion of the first volume of the liquid phase heat exchange fluid that undergoes the phase change is based on the second quantity of heat absorbed by the first volume of the liquid phase heat exchange fluid during the time period, wherein the first vapor-permeable membrane is configured to allow communication of the first portion of the vapor phase heat exchange fluid from the first liquid region, through the first vapor-permeable membrane, and into the first vapor region, and wherein the first vapor region comprises a first outlet configured to communicate the first volume of the vapor phase heat exchange fluid out of the first vapor region of the first membrane heat sink, In some embodiments, the system can further comprise a second computing device emitting a third quantity of heat during the time period and a second membrane heat sink collocated with the second computing device, the second membrane heat sink comprising a second liquid region and a second vapor region, the second liquid region being separated from the second vapor region by a second vapor-permeable membrane, the second liquid region comprising a second inlet configured to communicate a second volume of the liquid phase heat exchange fluid into the second liquid region, wherein the second membrane heat sink is configured to communicate a fourth quantity of heat from the second computing device into the second liquid region.

In some embodiments, the fourth quantity of heat is correlated with the third quantity of heat emitted from the second computing device during the time period, wherein the second volume of the liquid phase heat exchange fluid is configured to absorb the fourth quantity of heat communicated into the second liquid region during the time period such that at least a second portion of the second volume of the liquid phase heat exchange fluid undergoes the phase change to a second volume of the vapor phase heat exchange fluid. In some embodiments, a quantity of the second portion of the second volume of the liquid phase heat exchange fluid that undergoes the phase change is based on the fourth quantity of heat absorbed by the second volume of the liquid phase heat exchange fluid during the time period. In some embodiments, the second vapor-permeable membrane is configured to allow communication of the second portion of the vapor phase heat exchange fluid from the second liquid region, through the second vapor-permeable membrane, and into the second vapor region. In some embodiments, the second vapor region comprises a second outlet configured to communicate the second volume of the vapor phase heat exchange fluid out of the second vapor region of the second membrane heat sink.

In some embodiments, the system can further comprise a liquid phase heat exchange fluid reservoir configured to store a replenishing supply of the liquid phase heat exchange fluid, configured to communicate the first volume of the liquid phase heat exchange fluid into the first liquid region within the first membrane heat sink during the time period, and configured to communicate the second volume of the liquid phase heat exchange fluid into the second liquid region within the second membrane heat sink during the time period. In some embodiments, the system can further comprise a vapor phase heat exchange fluid recovery unit configured to cause a second phase change of the first and second volumes of the vapor phase heat exchange fluid back to liquid phase heat exchange fluid. In some embodiments, the system can further comprise a liquid phase heat exchange fluid distribution system in fluidic communication with the liquid phase heat exchange fluid reservoir, the first membrane heat sink, and the second membrane heat sink. In some embodiments, the liquid phase heat exchange fluid distribution system is configured to maintain the liquid phase heat exchange fluid within the liquid phase heat exchange fluid distribution system at a hydrostatic pressure within a predetermined range.

According to another embodiment, a method can be carried out for operating membrane-based heat sinks and membrane-based heat exchangers, as well as devices and systems, such as servers, server racks, server arrays, or data centers, configured for using the same to cool collocated computing devices therein/thereof. For example, a method can comprise collocating a membrane heat sink with a computing device, the computing device being configured to emit heat energy, the membrane heat sink being configured to absorb heat energy emitted from the computing device. In some embodiments, the membrane heat sink can comprise a liquid region comprising an inlet port configured to communicate a liquid phase heat exchange fluid into the liquid region. In some embodiments, the membrane heat sink can further comprise a vapor region comprising an outlet port configured to communicate a vapor phase heat exchange fluid out of the membrane heat sink. In some embodiments, the membrane heat sink can further comprise a vapor-permeable membrane disposed between the liquid region and the vapor region.

In some embodiments, the method can further comprise communicating a volume of the liquid phase heat exchange fluid into the liquid region of the membrane heat sink. The method can further comprise: allowing communication of the portion of heat energy emitted from the computing device collocated with the membrane heat sink into the liquid region, thereby allowing absorption, of at least a portion of the heat energy communicated into the liquid region, into the liquid phase heat exchange fluid being maintained within in the liquid region.

In some embodiments, the vapor-permeable membrane is further configured to allow communication therethrough of the vapor phase heat exchange fluid and disallow communication therethrough of the liquid phase heat exchange fluid. In some embodiments, the method can further comprise controlling a rate of communication of the vapor phase heat exchange fluid through the outlet port and out of the vapor region of the membrane heat sink based upon a rate of communication of the vapor phase heat exchange fluid through the vapor-permeable membrane from the liquid region to the vapor region. In some embodiments, the method can further comprise controlling a rate of communication of the liquid phase heat exchange fluid through the inlet port and into the liquid region based on the rate of communication of the vapor phase heat exchange fluid through vapor-permeable membrane from the liquid region to the vapor region. In some embodiments, the rate of communication of the vapor phase heat exchange fluid through the vapor-permeable membrane from the liquid region into the vapor region is based on a rate at which the liquid phase heat exchange fluid undergoes the phase change to the vapor phase heat exchange fluid. In some embodiments, the rate at which the liquid phase heat exchange fluid undergoes the phase change to the vapor phase heat exchange fluid is based upon a quantity of the excess heat absorbed by the liquid phase heat exchange fluid.

In some embodiments, the method can further comprise absorbing, during a first time, a first quantity of excess heat emitted by the collocated computing device, causing the liquid phase heat exchange fluid in the liquid region to undergo a phase change to the vapor phase heat exchange fluid at a first rate. In some embodiments, the volume of the liquid phase heat exchange fluid that undergoes the phase change to the vapor phase heat exchange fluid during the first time is based upon a first quantity of the excess heat absorbed by the liquid phase heat exchange fluid during the first time. In some embodiments, the method further comprises, absorbing, during a second time, a second quantity of excess heat emitted by the collocated computing device, causing the liquid phase heat exchange fluid in the liquid region to undergo the phase change to the vapor phase heat exchange fluid at a second rate. In some embodiments, the volume of the liquid phase heat exchange fluid that undergoes the phase change to the vapor phase heat exchange fluid during the second tie is based upon a second quantity of the excess heat absorbed by the liquid phase heat exchange fluid during the second time.

According to another embodiment, a method can be carried out that comprises providing a membrane heat sink device that comprises a first membrane heat sink and a second membrane heat sink. The method can comprise collocating, during a time period, the first membrane heat sink with a first computing device and the second membrane heat sink with a second computing device. In some embodiments, the first computing device can emit a first quantity of excess heat during the time period. In some embodiments, the first membrane heat sink comprises a first liquid region and a first vapor region. In some embodiments, the first liquid region can be separated from the first vapor region by a first vapor-permeable membrane. The first liquid region can comprise a first inlet and the method can further comprise communicating, during the time period, a first volume of a liquid phase heat exchange fluid into the first liquid region via the first inlet.

In some embodiments, the method can further comprise communicating a second quantity of excess heat from the first computing device into the first liquid region, the second quantity of excess heat being correlated with the first quantity of excess heat emitted from the first computing device during the time period. In some embodiments, the method can further comprise retaining the first volume of the liquid phase heat exchange fluid within the first liquid region during at least an initial portion of the time period such that the first volume of the liquid phase heat exchange fluid absorbs the second quantity of excess heat communicated into the first liquid region during the time period. In some embodiments, the method can further comprise causing at least a portion of the first volume of the liquid phase heat exchange fluid to undergo a phase change to a first volume of a vapor phase heat exchange fluid.

In some embodiments, a quantity of the portion of the first volume of the liquid phase heat exchange fluid that undergoes the phase change is based on the second quantity of excess heat absorbed by the first volume of the liquid phase heat exchange fluid during the time period. In some embodiments, the method can further comprise allowing communication of the first portion of the vapor phase heat exchange fluid from the first liquid region, through the first vapor-permeable membrane, and into the first vapor region. In some embodiments, the first vapor region comprises a first outlet, and the method can further comprise communicating the first volume of the vapor phase heat exchange fluid out of the first vapor region of the first membrane heat sink during the time period. In some embodiments, the first volume of the vapor phase heat exchange fluid communicated out of the first vapor region of the first membrane heat sink via the first outlet during the time period controls the first volume of the liquid phase heat exchange fluid communicated into the first liquid region of the first membrane heat sink via the first inlet port during the time period.

In some embodiments, the second membrane heat sink can be collocated during the time period with a second computing device emitting a third quantity of excess heat during the time period. In some embodiments, the second membrane heat sink comprises a second liquid region and a second vapor region, the second liquid region being separated from the second vapor region by a second vapor-permeable membrane. In some embodiments, the second liquid region comprises a second inlet, and the method can further comprise communicating a second volume of the liquid phase heat exchange fluid into the second liquid region during the time period. In some embodiments, the method can further comprise communicating a fourth quantity of excess heat from the second computing device into the second liquid region, the fourth quantity of excess heat being correlated with the third quantity of excess heat emitted from the second computing device during the time period.

In some embodiments, the method can further comprise retaining the second volume of the liquid phase heat exchange fluid in the second liquid region during at least an initial portion of the time period in order to allow the second volume of the liquid phase heat exchange fluid to absorb the fourth quantity of excess heat communicated into the second liquid region during the time period. In some embodiments, the method can further comprise allowing a portion of the second volume of the liquid phase heat exchange fluid to undergo the phase change to a second volume of the vapor phase heat exchange fluid in response to the second volume of the liquid phase heat exchange fluid absorbing the fourth quantity of excess heat communicated into the second liquid region during the time period.

In some embodiments, a quantity of the portion of the second volume of the liquid phase heat exchange fluid that undergoes the phase change is based on the fourth quantity of excess heat absorbed by the second volume of the liquid phase heat exchange fluid during the time period. In some embodiments, the method can further comprise communicating the second portion of the vapor phase heat exchange fluid from the second liquid region, through the second vapor-permeable membrane, and into the second vapor region. In some embodiments, the second vapor region comprises a second outlet and the method further comprises communicating the second volume of the vapor phase heat exchange fluid out of the second vapor region of the second membrane heat sink during the time period. In some embodiments, the second volume of the vapor phase heat exchange fluid communicated out of the second vapor region of the second membrane heat sink via the second outlet during the time period controls the second volume of the liquid phase heat exchange fluid communicated into the second liquid region of the second membrane heat sink via the second inlet port during the time period.

In some embodiments, the method can further comprise providing a liquid phase heat exchange fluid reservoir configured to store a replenishing supply of the liquid phase heat exchange fluid. In some embodiments, the method can further comprise communicating the first volume of the liquid phase heat exchange fluid into the first liquid region within the first membrane heat sink during the time period. In some embodiments, the method can further comprise communicating the second volume of the liquid phase heat exchange fluid into the second liquid region within the second membrane heat sink during the time period.

In some embodiments, the method can further comprise providing a vapor phase heat exchange fluid recovery unit. In some embodiments, the method can further comprise communicating the first and second volumes of the vapor phase heat exchange fluid into the vapor phase heat exchange fluid recovery unit. In some embodiments, the method can further comprise causing a second phase change of the first and second volumes of the vapor phase heat exchange fluid in the vapor phase heat exchange fluid recovery unit back to liquid phase heat exchange fluid.

In some embodiments, the method can further comprise providing a liquid phase heat exchange fluid distribution system in fluidic communication with the liquid phase heat exchange fluid reservoir, the first membrane heat sink, and the second membrane heat sink. The method can further comprise maintaining, using the liquid phase heat exchange fluid distribution system, a hydrostatic pressure of all liquid phase heat exchange fluid within the liquid phase heat exchange fluid distribution system within a predetermined hydrostatic pressure range.

According to another embodiment, a method for providing a system comprising one or more membrane heat sink devices can be carried out. The system can comprise a first membrane heat sink configured to be collocated with a first computing device. The first computing device emits a first quantity of heat during a time period. The first membrane heat sink can comprise a first liquid region and a first vapor region. In some embodiments, the first liquid region can be separated from the first vapor region by a first vapor-permeable membrane. In some embodiments, the first liquid region comprises a first inlet and the method can further comprise communicating a first volume of a liquid phase heat exchange fluid into the first liquid region. In some embodiments, the method can further comprise communicating a second quantity of heat from the first computing device into the first liquid region of the first membrane heat sink.

In some embodiments, the second quantity of heat can be correlated with the first quantity of heat emitted from the first computing device during the time period. In some embodiments, the method can further comprise causing absorption into the first volume of the liquid phase heat exchange fluid of the second quantity of heat communicated into the first liquid region during the time period. In some embodiments, the absorption of the second quantity of heat into the first liquid region during the time period can cause at least a first portion of the first volume of the liquid phase heat exchange fluid to undergo a phase change to a first volume of a vapor phase heat exchange fluid. In some embodiments, a quantity of the first portion of the first volume of the liquid phase heat exchange fluid that undergoes the phase change is based on the second quantity of heat absorbed by the first volume of the liquid phase heat exchange fluid during the time period. In some embodiments, the method can further comprise communicating the first portion of the vapor phase heat exchange fluid from the first liquid region, through the first vapor-permeable membrane, and into the first vapor region. In some embodiments, the first vapor region comprises a first outlet configured and the method can further comprise communicating the first volume of the vapor phase heat exchange fluid out of the first vapor region of the first membrane heat sink.

In some embodiments, the system can further comprise a second computing device emitting a third quantity of heat during the time period and a second membrane heat sink collocated with the second computing device. In some embodiments, the second membrane heat sink comprises a second liquid region and a second vapor region, the second liquid region being separated from the second vapor region by a second vapor-permeable membrane.

In some embodiments, the second liquid region comprises a second inlet and the method further comprises communicating a second volume of the liquid phase heat exchange fluid into the second liquid region via the second inlet. In some embodiments, the method can further comprise communicating a fourth quantity of heat from the second computing device into the second liquid region. In some embodiments, the fourth quantity of heat is correlated with the third quantity of heat emitted from the second computing device during the time period. In some embodiments, the second volume of the liquid phase heat exchange fluid is configured to absorb the fourth quantity of heat communicated into the second liquid region during the time period such that at least a second portion of the second volume of the liquid phase heat exchange fluid undergoes the phase change to a second volume of the vapor phase heat exchange fluid. In some embodiments, a quantity of the second portion of the second volume of the liquid phase heat exchange fluid that undergoes the phase change is based on the fourth quantity of heat absorbed by the second volume of the liquid phase heat exchange fluid during the time period. In some embodiments, the second vapor-permeable membrane is configured to allow communication of the second portion of the vapor phase heat exchange fluid from the second liquid region, through the second vapor-permeable membrane, and into the second vapor region. In some embodiments, the second vapor region comprises a second outlet configured to communicate the second volume of the vapor phase heat exchange fluid out of the second vapor region of the second membrane heat sink.

In some embodiments, the method can further comprise providing a liquid phase heat exchange fluid reservoir configured to store a replenishing supply of the liquid phase heat exchange fluid. In some embodiments, the method can further comprise communicating the first volume of the liquid phase heat exchange fluid from the liquid phase heat exchange fluid reservoir into the first liquid region within the first membrane heat sink during the time period. In some embodiments, the method further comprises communicating the second volume of the liquid phase heat exchange fluid into the second liquid region within the second membrane heat sink during the time period. In some embodiments, the method can further comprise providing a vapor phase heat exchange fluid recovery unit. In some embodiments, the method can further comprise communicating the first and second volumes of the vapor phase heat exchange fluid into the vapor phase heat exchange fluid recovery unit to cause a second phase change of the first and second volumes of the vapor phase heat exchange fluid back to liquid phase heat exchange fluid.

In some embodiments, the method can further comprise providing a liquid phase heat exchange fluid distribution system in fluidic communication with the liquid phase heat exchange fluid reservoir, the first membrane heat sink, and the second membrane heat sink. In some embodiments, the method can further comprise maintaining a hydrostatic pressure of the liquid phase heat exchange fluid in the liquid phase heat exchange fluid distribution system within a predetermined hydrostatic pressure range.

According to another embodiment, a dual-phase membrane heat sink system can comprise a heat exchange fluid reservoir configured to store a supply of a heat exchange fluid in a liquid phase; and a plurality of membrane heat sinks in fluidic communication with the heat exchange fluid reservoir, wherein respective membrane heat sinks of the plurality of membrane heat sinks are configured to be collocated with respective computing devices of a plurality of computing devices. In some embodiments, each of the plurality of membrane heat sinks comprise: a bottom structure defining a first portion of an inner volume of the membrane heat sink, the bottom structure comprising a liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure.

In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes phase change of an amount equal to the volume of the incoming heat exchange fluid from the liquid phase to a vapor phase. In some embodiments, the vapor-permeable membrane is configured to allow the portion of the volume of the heat exchange fluid that changes phase from the liquid to vapor to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the dual-phase membrane heat sink system further comprises: a heat exchange fluid recovery unit configured to cause a second phase change of the volume of the heat exchange fluid in the vapor phase back to the liquid phase. In some embodiments, the dual-phase membrane heat sink system further comprises: a heat exchange fluid distribution system in fluidic communication with the heat exchange fluid reservoir and the plurality of membrane heat sinks.

In some embodiments, the heat exchange fluid distribution system is configured to maintain the heat exchange fluid within the heat exchange fluid distribution system at a hydrostatic pressure within a predetermined range.

According to another embodiment, a server cluster can be provided that is configured for data processing in a data center, the server cluster comprising: a plurality of computing devices arranged in a plurality of server racks, each server rack of the plurality of server racks comprising two or more of the plurality of computing devices; a heat exchange fluid reservoir configured to store a supply of a heat exchange fluid in a liquid phase; and a plurality of membrane heat sinks in fluidic communication with the heat exchange fluid reservoir, wherein respective membrane heat sinks of the plurality of membrane heat sinks are configured to be collocated with respective computing devices of the plurality of computing devices. In some embodiments, each of the plurality of membrane heat sinks comprise: a bottom structure defining a first portion of an inner volume of the membrane heat sink, the bottom structure comprising a liquid inlet at least partially defined by an aperture through the bottom structure, the liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure. In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes a phase change of at least a portion of the volume of the heat exchange fluid from the liquid phase to a vapor phase. In some embodiments, the vapor-permeable membrane is configured to allow the portion of the volume of the heat exchange fluid that changes phase from liquid to vapor to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the server cluster further comprises: a heat exchange fluid recovery unit configured to cause a second phase change of the volume of the heat exchange fluid in the vapor phase back to the liquid phase. In some embodiments, the server cluster further comprises: a heat exchange fluid distribution system in fluidic communication with the heat exchange fluid reservoir and the plurality of membrane heat exchangers.

In some embodiments, the heat exchange fluid distribution system is configured to maintain the heat exchange fluid within the heat exchange fluid distribution system at a hydrostatic pressure within a predetermined range. In some embodiments, the heat exchange fluid reservoir is further configured to cause a second phase change of the volume of the heat exchange fluid in the vapor phase back to the liquid phase. In some embodiments, excess heat removed from the heat exchange fluid reservoir is transferred to a server cluster primary loop of the data center and heat exchange fluid converted back to the liquid phase is transferred back to a primary liquid cooling loop of the data center.

According to another embodiment, a heat sink array can be provided that is configured for cooling a server cluster comprising a plurality of server racks, the heat sink array being configured to be collocated with the server cluster, the heat sink array comprising: a heat exchange fluid reservoir configured to store a supply of a heat exchange fluid in a liquid phase; a plurality of heat exchangers, each of the plurality of heat exchanges configured to be collocated with respective servers of one of the server racks in the server cluster, each of the plurality of heat exchangers comprising an inner volume, a vapor-permeable membrane dimensioned and configured to divide the inner volume of the heat exchanger into at least a first portion and a second portion, a liquid fluid inlet, and a vapor fluid outlet. In some embodiments, the liquid fluid inlet is configured to allow a liquid volume of the heat exchange fluid to be communicated into the first portion of the inner volume of the heat exchanger. In some embodiments, in response to the liquid volume of the heat exchange fluid being exposed to heat from one or more computing entities in one or more server racks of the server cluster collocated with the heat exchanger, at least a portion of the liquid volume of the heat exchange fluid phase changes into a vapor volume of the heat exchange fluid. In some embodiments, the vapor-permeable membrane is configured to allow heat exchange fluid in a vapor phase to be communicated therethrough from the first portion of the inner volume of the heat exchanger to the second portion of the inner volume of the heat exchanger and disallow heat exchange fluid in a liquid phase to be communicated therethrough from the first portion of the inner volume of the heat exchanger to the second portion of the inner volume of the heat exchanger. In some embodiments, the vapor outlet is configured to allow communication of some or all of the vapor volume of the heat exchange fluid to be communicated out of the heat exchanger following the communication of vapor volume of the heat exchange fluid through the vapor-permeable membrane and into the second portion of the inner volume of the heat exchange fluid following the phase change.

According to another embodiment, a heat exchanger device can be provided that comprises: a heat exchange fluid reservoir configured to store a replenishing supply of a heat exchange fluid in a liquid phase; a heat exchanger in fluidic communication with the heat exchange fluid reservoir, the heat exchanger being configured to receive a liquid volume of the heat exchange fluid, expose the liquid volume of the heat exchange fluid to waste heat from one or more collocated computing devices such that at least some of the liquid volume of the heat exchange fluid undergoes a phase change from a liquid phase to a vapor change, and allow communication of a vapor volume of the heat exchange fluid out of the heat exchanger; and a heat exchange fluid recovery unit in fluidic communication with the heat exchanger, the heat exchange fluid recovery unit being configured to cause a further phase change of the vapor volume of the heat exchange fluid from the vapor phase to the liquid phase. In some embodiments, the heat exchanger comprises a vapor-permeable membrane interposed between a first portion of the inner volume of the heat exchanger and a second portion of the inner volume of the heat exchanger.

In some embodiments, the heat exchanger further comprises: a bottom structure defining a first portion of an inner volume of the heat exchanger, the bottom structure comprising a liquid inlet at least partially defined by an aperture through the bottom structure, the liquid inlet being configured to allow the liquid volume of the heat exchange fluid to be communicated from the heat exchange fluid reservoir into the first portion of the inner volume of the heat exchanger. In some embodiments, the heat exchanger further comprises: a top structure defining a second portion of the inner volume of the heat exchanger, the top structure comprising a vapor outlet at least partially defined by an aperture through the top structure, the vapor outlet being configured to allow a volume of the heat exchange fluid in a fluid phase to be communicated out of the second portion of the inner volume of the heat exchanger.

In some embodiments, a portion of a first surface of the vapor-permeable membrane is sealably joined to an inside surface of the bottom structure and a portion of a second surface of the vapor-permeable membrane is sealably joined to an inside surface of the top structure. In some embodiments, the bottom structure of the heat exchanger is configured to allow said exposure of the liquid volume of the heat exchange fluid to said waste heat from the one or more collocated computing devices. In some embodiments, the vapor outlet is configured to allow communication of some or all of the vapor volume of the heat exchange fluid out of the heat exchange following the communication of vapor volume of the heat exchange fluid through the vapor-permeable membrane and into the second portion of the inner volume of the heat exchange fluid following the phase change. In some embodiments, the vapor-permeable membrane is configured to prevent communication therethrough of the heat exchange fluid in the liquid phase, thereby protecting said heat-generating component from liquid-related damage. In some embodiments, the heat exchanger device is configured to efficiently dissipate said waste heat generated by the one or more collocated computing devices, thereby increasing an overall thermal performance of said one or more collocated computing devices.

Some embodiments of the present disclosure describe two-phase heat sinks that utilize nucleate boiling at a predefined liquid-vapor interface as the primary mode of heat transfer. In one embodiment, liquid and vapor microchannels are separated by arrays of evenly spaced posts, which enhance liquid inflow to the surface structures through wicking action. Bubbles and vapor columns form at the interface and are rapidly expelled to the vapor space above the membrane. This configuration helps mitigate instability issues commonly associated with randomly expanding evaporative interfaces during boiling. While not bound to any specific theory, this improved stability may result from the rapid removal of vapor following the phase change and its flux through the vapor-permeable membrane.

The proposed heat sink system addresses the challenges associated with traditional cooling methods by integrating a vapor-permeable membrane with each computing device in a server rack. This membrane, strategically positioned in proximity to the heat-generating components, enables efficient heat dissipation through the process of vapor transport. Simultaneously, it acts as a protective barrier against liquid ingress, safeguarding the computing devices from potential damage. In some embodiments, the membrane can serve as a mass controller, thereby reducing or eliminating the need for expensive mass controllers that are typically required if a heat sink allows liquid to exit the heat sink. Conversely, conventional heat sinks and heat exchange systems typically experience flow maldistribution, and therefore require mass flow control of heat exchange fluid through the system.

In some embodiments, such a heat sink can be operated at least partially using hydrostatic pressure. Without wishing to be bound by any particular theory, as heat exchange fluid in one of the disclosed heat exchangers experiences a phase change from a liquid state to a vapor state, bubbles of heat exchange fluid in the vapor phase are formed in the remaining liquid heat exchange fluid, and the bubbles (vapor heat exchange fluid) exit the heat exchanger by being communicated through a vapor-permeable membrane that disallows any heat exchange fluid in a liquid state to be communicated therethrough. Without wishing to be bound by any particular theory, this may result in a low pressure change (e.g., low pressure drop) between upstream heat exchange fluid in the liquid state, a first portion of the inner volume of the heat exchanger where the phase change occurs, a second portion of the inner volume of the heat exchanger separated from the first portion by the vapor-permeable membrane, and an outlet side of the second portion of the heat exchanger where heat exchange fluid in the vapor phase is communicated out of the heat exchanger. The pressure change experienced by the heat exchangers disclosed herein is typically lower—in some cases much lower-than the pressure change experienced by conventional heat exchangers where the partial pressure can often change drastically as an increasing percentage of liquid becomes vapor and the vapor is not able to quickly escape the heat exchanger.

According to some embodiments, a dual-phase membrane heat sink system can be provided that comprises: a heat exchange fluid reservoir configured to store a supply of a heat exchange fluid in a liquid phase; and a plurality of membrane heat sinks in fluidic communication with the heat exchange fluid reservoir, wherein respective membrane heat sinks of the plurality of membrane heat sinks are configured to be collocated with respective computing devices of a plurality of computing devices. In some embodiments, each of the plurality of membrane heat sinks comprise: a bottom structure defining a first portion of an inner volume of the membrane heat sink, the bottom structure comprising a liquid inlet at least partially defined by an aperture through the bottom structure, the liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure. In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes a phase change of at least a portion of the volume of the heat exchange fluid from the liquid phase to a vapor phase. In some embodiments, the vapor-permeable membrane is configured to allow the portion of the volume of the heat exchange fluid that phase changes from the liquid phase to the vapor phase to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the dual-phase membrane heat sink system further comprises: a heat exchange fluid recovery unit configured to cause a second phase change of the volume of the heat exchange fluid in the vapor phase back to the liquid phase. In some embodiments, the dual-phase membrane heat sink system further comprises: a heat exchange fluid distribution system in fluidic communication with the heat exchange fluid reservoir and the plurality of membrane heat exchangers.

In some embodiments, the heat exchange fluid distribution system is configured to maintain the heat exchange fluid within the heat exchange fluid distribution system at a hydraulic pressure within a predetermined range.

According to another embodiment, a server cluster can be provided that comprises: a plurality of computing devices arranged in a plurality of server racks, each server rack of the plurality of server racks comprising two or more of the plurality of computing devices; a heat exchange fluid reservoir configured to store a supply of a heat exchange fluid in a liquid phase; and a plurality of membrane heat sinks in fluidic communication with the heat exchange fluid reservoir, wherein respective membrane heat sinks of the plurality of membrane heat sinks are configured to be collocated with respective computing devices of the plurality of computing devices. In some embodiments, each of the plurality of membrane heat sinks comprise: a bottom structure defining a first portion of an inner volume of the membrane heat sink, the bottom structure comprising a liquid inlet at least partially defined by an aperture through the bottom structure, the liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure. In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes a phase change of at least a portion of the volume of the heat exchange fluid from the liquid phase to a vapor phase. In some embodiments, the vapor-permeable membrane is configured to allow the portion of the volume of the heat exchange fluid that phase changes from the liquid phase to the vapor phase to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the server cluster can further comprise: a heat exchange fluid recovery unit configured to cause a second phase change of the volume of the heat exchange fluid in the vapor phase back to the liquid phase. In some embodiments, the server cluster can further comprise: a heat exchange fluid distribution system in fluidic communication with the heat exchange fluid reservoir and the plurality of membrane heat exchangers.

In some embodiments, the heat exchange fluid distribution system is configured to maintain the heat exchange fluid within the heat exchange fluid distribution system at a hydrostatic pressure within a predetermined range, sufficient to overcome the heat sink pressure drop without significantly impacting the heat sink saturation pressure and temperature. For example, in an example system, a pressure drop across the heat exchanger(s) may be less than or equal to about 5 kpa. As such, the hydrostatic pressure of liquid phase heat exchange fluid upstream of the heat exchanger(s) can be maintained between about 0.5 kpa and about 5 kpa such that a consistent supply of liquid phase heat exchange fluid is provided to the liquid inlet of the heat exchanger(s). The predetermined range may be based on predetermined hydrostatic pressure values above a mean or average pressure drop across the heat exchangers, a minimum pressure drop across the heat exchangers, a maximum pressure drop across the heat exchangers, a median pressure drop across the heat exchangers, and/or the like.

Heat exchange fluid demand will vary between different heat exchangers based on the heat generated at each of the collocated computing devices (e.g., GPUs, CPUs, chipsets, servers, racks, etc.). Since the hydrostatic pressure of the liquid phase heat exchange fluid upstream of the heat exchanger(s) should be maintained within a predetermined range above the pressure drop experienced across the heat exchanger(s) (e.g., maximum pressure drop), decreasing the maximum pressure drop experienced across the heat exchangers may result in a decrease in the predetermined range for hydrostatic pressure of the liquid phase heat exchange fluid that must be maintained upstream of the heat exchangers.

For example, a conventional heat exchanger may have a maximum pressure drop across the heat exchanger of 5 kpa, such that a good rule of thumb would be to maintain the upstream liquid phase heat exchange fluid at a hydrostatic pressure of between 0.5 kpa and 5 kpa. Conversely, an example heat exchanger as disclosed herein may experience a maximum pressure drop across the heat exchanger of 2 kpa, meaning that the upstream liquid phase heat exchange fluid should be maintained at a hydrostatic pressure of between 3 kpa and 5 kpa. The benefits of the disclosed systems are numerous, including that a lower range of hydrostatic pressure for the upstream liquid phase heat exchange fluid may mean that the system could work passively, as a thermosyphon, or smaller scale infrastructure and components such as pumps, meters, and the like, may be required. Further, a lower range of hydrostatic pressure for the upstream liquid phase heat exchange fluid may mean that less mechanically durable, and therefore less expensive, materials can be used for the heat exchanger, the inlet piping, the vapor-permeable membrane, and other components and materials that directly or indirectly contact the heat exchange fluid. Also, a lower range of hydrostatic pressure for the upstream liquid phase heat exchange fluid may result in a lower probability of material/component failures, heat exchange fluid leaks and spills, and the like. This can improve the safety of the system for human operators, reduce detrimental environmental impacts from undesirable release of heat exchange fluid, reduce operating costs, reduce system downtime, reduce preventative maintenance and repairs, and/or the like.

According to another embodiment, a heat sink array can be provided that is configured for cooling a server cluster comprising a plurality of server racks, the heat sink array being configured to be collocated with the server cluster. In some embodiments, the heat sink array comprises: a heat exchange fluid reservoir configured to store a supply of a heat exchange fluid in a liquid phase; a plurality of heat exchangers, each of the plurality of heat exchanges configured to be collocated with respective servers of one of the server racks in the server cluster, each of the plurality of heat exchangers comprising an inner volume, a vapor-permeable membrane dimensioned and configured to divide the inner volume of the heat exchanger into at least a first portion and a second portion, a liquid fluid inlet, and a vapor fluid outlet. In some embodiments, the liquid inlet is configured to allow a liquid volume of the heat exchange fluid to be communicated into the first portion of the inner volume of the heat exchanger. In some embodiments, in response to the liquid volume of the heat exchange fluid being exposed to heat from one or more computing entities in one or more server racks of the server cluster collocated with the heat exchanger, at least a portion of the liquid volume of the heat exchange fluid phase changes into a vapor volume of the heat exchange fluid. In some embodiments, the vapor-permeable membrane is configured to allow heat exchange fluid in a vapor phase to be communicated therethrough from the first portion of the inner volume of the heat exchanger to the second portion of the inner volume of the heat exchanger and disallow heat exchange fluid in a liquid phase to be communicated therethrough from the first portion of the inner volume of the heat exchanger to the second portion of the inner volume of the heat exchanger. In some embodiments, the vapor outlet is configured to allow communication of some or all of the vapor volume of the heat exchange fluid to be communicated out of the heat exchange following the communication of vapor volume of the heat exchange fluid through the vapor-permeable membrane and into the second portion of the inner volume of the heat exchange fluid following the phase change.

According to another embodiment, a heat exchanger device can be provided that comprises: a heat exchange fluid reservoir configured to store a replenishing supply of a heat exchange fluid in a liquid phase; a heat exchanger in fluidic communication with the heat exchange fluid reservoir, the heat exchange being configured to receive a liquid volume of the heat exchange fluid, expose the liquid volume of the heat exchange fluid to waste heat from one or more collocated computing devices such that at least some of the liquid volume of the heat exchange fluid undergoes a phase change from a liquid phase to a vapor change, and allow communication of a vapor volume of the heat exchange fluid out of the heat exchanger; and a heat exchange fluid recovery unit in fluidic communication with the heat exchanger, the heat exchange fluid recovery unit being configured to cause a further phase change of the vapor volume of the heat exchange fluid from the vapor phase to the liquid phase. In some embodiments, the heat exchanger comprises a vapor-permeable membrane interposed between a first portion of the inner volume of the heat exchanger and a second portion of the inner volume of the heat exchanger.

In some embodiments, the heat exchanger further comprises: a bottom structure defining a first portion of an inner volume of the heat exchanger, the bottom structure comprising a liquid inlet at least partially defined by an aperture through the bottom structure, the liquid inlet being configured to allow the liquid volume of the heat exchange fluid to be communicated from the heat exchange fluid reservoir into the first portion of the inner volume of the heat exchanger; a top structure defining a second portion of the inner volume of the heat exchanger, the top structure comprising a vapor outlet at least partially defined by an aperture through the top structure, the vapor outlet being configured to allow a volume of the heat exchange fluid in a fluid phase to be communicated out of the second portion of the inner volume of the heat exchanger.

In some embodiments, a portion of a first surface of the vapor-permeable membrane is sealably joined to an inside surface of the bottom structure and a portion of a second surface of the vapor-permeable membrane is sealably joined to an inside surface of the top structure.

In some embodiments, the bottom structure of the heat exchanger is configured to allow said exposure of the liquid volume of the heat exchange fluid to said waste heat from the one or more collocated computing devices.

In some embodiments, the vapor outlet is configured to allow communication of some or all of the vapor volume of the heat exchange fluid to be communicated out of the heat exchange following the communication of vapor volume of the heat exchange fluid through the vapor-permeable membrane and into the second portion of the inner volume of the heat exchange fluid following the phase change.

In some embodiments, the vapor-permeable membrane is configured to prevent communication therethrough of the heat exchange fluid in the liquid phase, thereby protecting said heat-generating component from liquid-related damage.

In some embodiments, the heat exchanger device is configured to efficiently dissipate said waste heat generated by the one or more collocated computing devices, thereby increasing an overall thermal performance of said one or more collocated computing devices.

### BRIEF DESCRIPTION OF THE DRAWINGS

Having thus described the invention in general terms, reference will now be made to the accompanying drawings. The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1 illustrates a conventional heat exchanger system for a server array, according to an embodiment of the present disclosure.

FIG. 2 illustrates several possible regimes for vapor fluid formation and flow within a heat exchanger, according to embodiments of the present disclosure.

FIG. 3 illustrates several possible regimes for vapor fluid formation and flow within a heat exchanger, according to embodiments of the present disclosure.

FIG. 4 illustrates vapor bubble formation and vapor bubble transport through the vapor-permeable membrane, according to an embodiment of the present disclosure.

FIG. 5 illustrates vapor bubble formation and vapor bubble transport through the vapor-permeable membrane, according to an embodiment of the present disclosure.

FIG. 6 is a micrograph of an interface of vapor-phase heat exchange fluid across the vapor-permeable membrane.

FIG. 7 is a heat map of a chipset collocated with a heat exchanger, according to an embodiment of the present disclosure.

FIG. 8 illustrates the heat flow pathway for conventional versus phase change heat exchange systems, according to an embodiment of the present disclosure.

FIG. 9 is a graph illustrating heat transfer coefficients (HTC) versus heat flux for a variety of heat exchange fluids contemplated, in accordance with an embodiment of the present disclosure.

FIG. 10 illustrates a phase-changing heat exchange system to maintain sufficiently low operating temperatures for computing devices of a Membrane Heat Sink (MHS)-enabled rack for a data center, in accordance with an embodiment of the present disclosure.

FIG. 11 illustrates an MHS-enabled rack for a data center, in accordance with an embodiment of the present disclosure.

FIG. 12 illustrates a server rack collocated with a heat exchange system provisioned with volumes of heat exchange fluid, in accordance with an embodiment of the present disclosure.

FIG. 13 illustrates a server array configured into server racks that each are provisioned with volumes of heat exchange fluid, in accordance with an embodiment of the present disclosure.

FIG. 14 illustrates a server array configured into server racks that each are provisioned with volumes of heat exchange fluid, in accordance with an embodiment of the present disclosure.

FIG. 15 illustrates a schematic of an example computing device according to any of the approaches or methods of the present disclosure.

FIG. 16 is a block flow diagram of an example method for implementing dual-phase membrane separation heat sinks for cooling collocated computing devices, in accordance with various embodiments disclosed herein.

FIG. 17 is a block flow diagram of an example method for fluid mass flow balancing within a dual-phase membrane separation heat sink system configured for cooling collocated computing devices, in accordance with various embodiments disclosed herein.

FIG. 18 is a block flow diagram of an example method for fluid mass flow balancing within a dual-phase membrane separation heat sink system configured for cooling collocated computing devices, in accordance with various embodiments disclosed herein.

FIG. 19 is a block flow diagram of an example method for fluid mass flow balancing within a dual-phase membrane separation heat sink system configured for cooling collocated computing devices, in accordance with various embodiments disclosed herein.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments of the present disclosure will now be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “exemplary” are used to be examples with no indication of quality level. Like numbers refer to like elements throughout.

As used herein, the terms “instructions,” “file,” “designs,” “data,” “content,” “information,” and similar terms may be used interchangeably, according to some example embodiments described herein, to refer to data capable of being transmitted, received, operated on, displayed, and/or stored. Thus, use of any such terms should not be taken to limit the spirit and scope of the disclosure. Further, where a computing device is described herein to receive data from another computing device, it will be appreciated that the data may be received directly from the other computing device or may be received indirectly via one or more computing devices, such as, for example, one or more servers, relays, routers, network access points, base stations, and/or the like.

As used herein, the term “computer-readable medium” refers to any medium configured to participate in providing information to a processor, including instructions for execution. Such a medium may take many forms, including, but not limited to a non-transitory computer-readable storage medium (for example, non-volatile media, volatile media), and transmission media. Transmission media include, for example, coaxial cables, copper wire, fiber optic cables, and carrier waves that travel through space without wires or cables, such as acoustic waves and electromagnetic waves, including radio, optical, and infrared waves. Signals include man-made transient variations in amplitude, frequency, phase, polarization, or other physical properties transmitted through the transmission media. Examples of non-transitory computer-readable media include a floppy disk, a flexible disk, hard disk, magnetic tape, any other non-transitory magnetic medium, a compact disc read only memory (CD-ROM), compact disc compact disc-rewritable (CD-RW), digital versatile disc (DVD), Blu-Ray, any other non-transitory optical medium, punch cards, paper tape, optical mark sheets, any other physical medium with patterns of holes or other optically recognizable indicia, a random access memory (RAM), a programmable read only memory (PROM), an erasable programmable read only memory (EPROM), a FLASH-EPROM, any other memory chip or cartridge, a carrier wave, or any other non-transitory medium from which a computer can read. The term computer-readable storage medium is used herein to refer to any computer-readable medium except transmission media. However, it will be appreciated that where embodiments are described to use a computer-readable storage medium, other types of computer-readable mediums may be substituted for or used in addition to the computer-readable storage medium in alternative embodiments.

As used herein, the term “circuitry” refers to all of the following: (a) hardware-only circuit implementations (such as implementations in only analog and/or digital circuitry); (b) to combinations of circuits and computer program product(s) comprising software (and/or firmware instructions stored on one or more computer readable memories), such as (as applicable): (i) to a combination of processor(s) or (ii) to portions of processor(s)/software (including digital signal processor(s)), software, and memory(ies) that work together to cause an apparatus, such as a mobile phone or server, to perform various functions described herein); and (c) to circuits, such as, for example, a microprocessor(s) or a portion of a microprocessor(s), that require software or firmware for operation, even if the software or firmware is not physically present. This definition of “circuitry” applies to all uses of this term in this application, including in any claims. As a further example, as used in this application, the term “circuitry” would also cover an implementation of merely a processor (or multiple processors) or portion of a processor and its (or their) accompanying software and/or firmware. The term “circuitry” would also cover, for example and if applicable to the particular claim element, a baseband integrated circuit or applications processor integrated circuit for a mobile phone or a similar integrated circuit in a server, a cellular network device, other network device, and/or other computing device.

As used herein, the term “computing device” refers to a specialized, centralized device, network, or system, comprising at least a processor and a memory device including computer program code, and configured to provide guidance or direction related to the charge transactions carried out in one or more charging networks.

As used herein, the terms “about,” “substantially,” and “approximately” generally mean plus or minus 10% of the value stated, e.g., about 250 μm would include 225 μm to 275 μm, about 1,000 μm would include 900 μm to 1,100 μm. Any provided value, whether or not it is modified by terms such as “about,” “substantially,” or “approximately,” all refer to and hereby disclose associated values or ranges of values thereabout, as described above.

Heat sink systems can be designed for use within a server farm, server rack, or the like, which can house a plurality of computing devices. These computing devices may include, but are not limited to, servers, processors, graphics processing units (GPUs), or any other heat-generating components commonly found in data center environments.

The short and long-term operability and reliability of these GPUs/CPUs may rely, at least in part, on the temperature being maintained at a sufficiently low level. In some embodiments, a heat sink/heat exchange system can be provided that comprises one or more vapor-permeable membranes. The membrane is constructed from materials with inherent vapor-permeability characteristics, such as nanostructures, microstructures, hydrophobicity/hydrophilicity, surface textures, or the like. The membrane can be configured to allow the passage of vapor molecules while effectively blocking the entry of liquid molecules. Examples of suitable materials include advanced polymers, ceramics, or composite materials designed to withstand the environmental conditions within a server rack.

The vapor-permeable membrane is strategically collocated with the heat-generating components of each computing device. This positioning optimizes the heat transfer process, ensuring that generated heat is efficiently conducted through the membrane and dissipated into the external environment.

In some embodiments, a primary function of the vapor-permeable membrane is to facilitate the transfer of heat from the heat-generating components to the surrounding environment through the process of vapor transport. As heat is generated, liquid molecules undergo a phase change to vapor molecules, and vapor molecules pass through the membrane, carrying thermal energy away from the computing device. This mechanism enhances the overall thermal performance of the server rack.

In addition to its role in heat dissipation, the vapor-permeable membrane serves as a protective barrier against liquid ingress. By preventing the entry of liquids, such as water or coolant, the membrane safeguards the computing devices from potential damage caused by liquid-related incidents.

Described herein are vapor-permeable heat sink systems that offer several advantages over traditional cooling methods, including: enhanced heat dissipation efficiency, protection against liquid-related damage, reduced maintenance requirements, and/or improved reliability and longevity of computing devices.

In some embodiments, an advanced thermal management system meticulously crafted for server rack environments, addressing the incessant challenges posed by escalating heat generation. The innovative heat sink system integrates vapor-permeable membranes with computing devices within a server rack, marking a paradigm shift in thermal performance optimization.

The relentless drive for increased computational capabilities in data centers has led to a concurrent surge in heat generation, necessitating advanced thermal management solutions. This heat sink system transcends conventional cooling methods, offering a holistic approach that efficiently dissipates heat while concurrently safeguarding computing devices from liquid-related threats. The evolving landscape of high-performance computing environments demands not only enhanced thermal efficiency but also the prevention of downtime, a critical consideration in the context of mission-critical server operations.

Described is a highly sophisticated heat sink system designed to efficiently dissipate heat and protect computing devices from liquid-related incidents, overheating, and/or other issues. The integration of vapor-permeable membranes enables precise thermal management.

In some embodiments, a heat sink system accommodates a diverse array of computing devices commonly found in modern server racks, including servers, central processing units (CPUs), graphics processing units (GPUs), accelerators, and other computing elements.

In some embodiments, strategic placement of the vapor-permeable membrane can help improve thermal transfer efficiency. In many instances, simple collocation of each phase change heat sink/heat rack is a suitable or even an optimal placement approach with regard to latent heat removal efficiency.

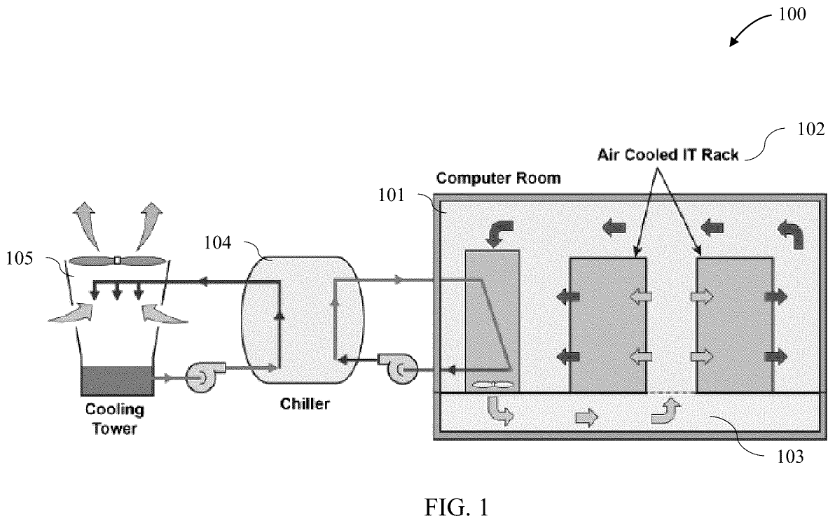

Referring now to FIG. 1, a vapor-permeable membrane-based heat sink system 100 is illustrated which comprises a computer room 101. In the computer room 101 is one or more computing devices (not shown) and one or more heat exchangers 102 comprising one or more vapor-permeable membranes collocated with the one or more computing devices. A heat exchange fluid 103 is configured to absorb waste heat generated by collocated computing devices when in a heat exchanger 102. The heat exchange fluid 103 undergoes a phase change from a liquid phase to a vapor phase due to the resulting temperature change upon absorbing the waste heat. The heat exchanges 102 are configured to separate a vapor volume of the heat exchange fluid 103 from a liquid phase to a vapor phase such that a vapor volume of the heat exchange fluid is configured to be transported through a respective vapor-permeable membrane in each heat exchanger.

The vapor-permeable membrane-based heat sink system 100 represents a pioneering and comprehensive solution to the evolving challenges in server rack thermal management. The intricate integration of vapor-permeable membranes, advanced materials, and innovative coolants provides a holistic and efficient approach to dissipating heat while ensuring the longevity and reliability of critical infrastructure within data centers. The disclosed vapor-permeable membrane-based heat sink system 100 disclosed herein stands as a testament to the continuous innovation required to meet the demands of contemporary data center architectures, offering a robust and scalable solution for the evolving landscape of high-performance computing environments. The incorporation of advanced thermal management systems, redundancies, downtime prevention mechanisms, and meticulous coolant mass flow management further solidifies its position as a transformative technology in the field of server rack optimization.

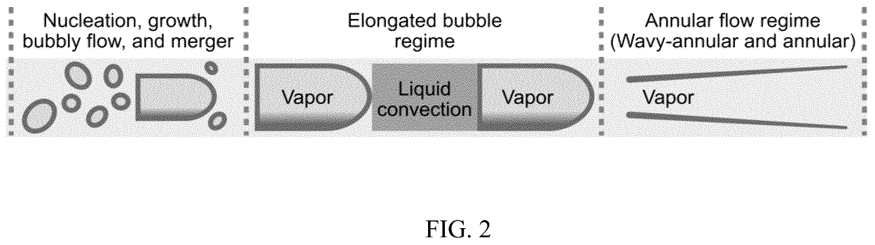

FIG. 2 illustrates several vapor formation regimes, according to several embodiments disclosed herein. Nucleation of microbubbles in the liquid phase heat exchange fluid can occur in the heat exchanger due to heat transfer from a collocated computing device/rack into the liquid phase heat exchange fluid. The microbubbles can grow through bubble combination, and a flow of bubbles can merge into an elongated bubble, according to an elongated bubble regime. Bubbles can be elongated due to several different factors, such as the turbulence caused by bubble flow, can be elongated in the direction of liquid flow due to the flow of liquid phase heat exchange fluid and/or along an inner surface of a heat exchanger. Elongated bubbles of vapor phase heat exchange fluid can be formed via convection of heat through liquid phase heat exchange fluid in the heat exchanger. In some embodiments, in an annular flow regime, two-phase gas-liquid flow can occur when high-gas and low-liquid superficial velocities occur. The annular flow regime can be annular or wavy-annular. The vapor bubbles can flow in a variety of states or according to a variety of regimes, which can change as gas flow rate or liquid-gas flow rate increases. The regimes can include, e.g., a truly bubbly state, as one or more slugs through channels or apertures, in a churn state, as wispy-annular or wavy-annular, and/or as truly annular.

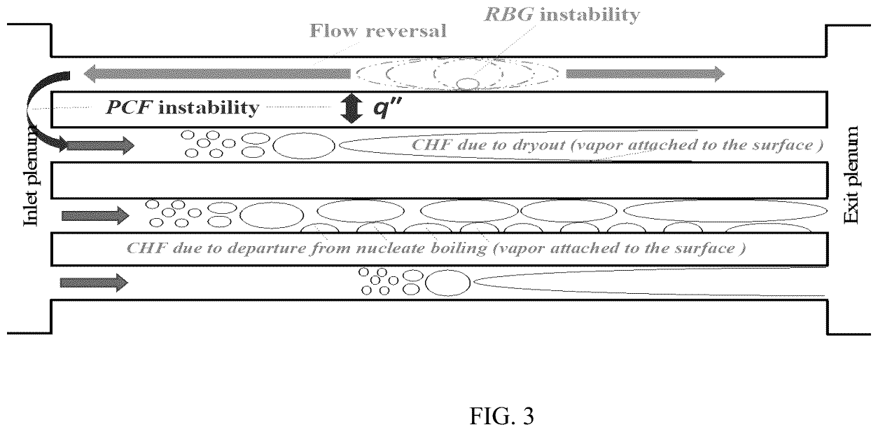

FIG. 3 further illustrates several flow regimes through internal channels of a heat exchanger between an inlet plenum and an exit plenum. The heat convection/absorption by the liquid phase heat exchanger fluid in the channels can be impacted by surface area and material type, channel diameter or height (q″). Flow instability or reversal may occur in some cases due to liquid to vapor pressure drop, incrustation, scaling, biological growth, sediment, fluid flow turbulence, surface adhesion, fluid flow velocity changes, fluid temperature changes, and/or the like. The plane Poiseuille-Couette flow (PCF) of the fluid in the channels, which can be stable to small disturbances for various values of Reynolds number in the absence of vertical throughflow, may become unstable owing to the change in the sign of growth rate depending on the magnitude of throughflow, such as when mixing of vapor and liquid phases of the fluids occur in turbulent stratified flows.

In some embodiments, the critical heat flux (CHF) of liquid phase fluid to vapor phase fluid in a channel can change due to vapor being attached to an inner surface of a channel, due to the departure of nucleated/boiling fluid due to vapor being attached to the surface, or otherwise.

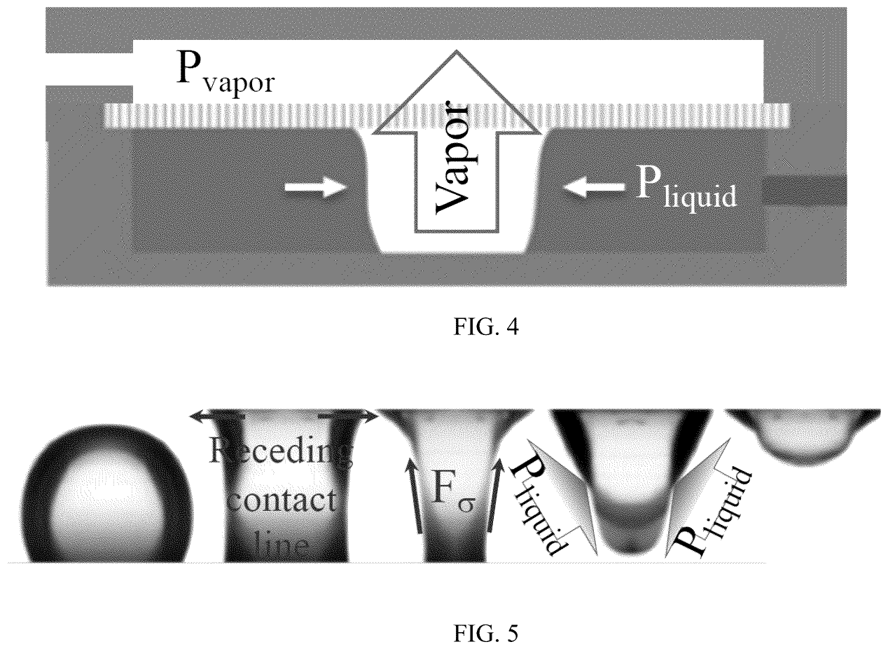

Referring now to FIG. 4, a side-view of a vapor-permeable membrane-based heat sink is shown. According to some embodiments, liquid enters the vapor-permeable membrane-based heat sink at a constant temperature and pressure (P_{liquid}). The vapor-permeable membrane-based heat sink can be separated into a liquid region and a vapor region. The fluid temperature at the topside of the field is at saturation temperature, while the top surface of the solid is assumed to be a free convection wall. As illustrated, vapor exits the device at a constant pressure. The flow field is discretized by a uniform computational grid. The grid dimensions of the computational domain were 0.2 μm in all three directions. A grid independence study ensured that the computational results are independent of the grid size. The maximum error in the calculations of local wall heat flux and evaporative mass flux were found, according to some examples, to be less than 3% when the grid size was reduced, e.g., by a factor of two.

As shown in FIG. 5, the impact of vapor-permeable membrane structure and material use on heat exchange fluid flow through microchannels is shown. As shown, the heat exchange fluid forms a meniscus, and the contact line of the heat exchange fluid to the microchannel structure was shown to affect the shape and position of the meniscus. At low pressure, the interface curvature is almost zero and surface friction force acting on the interface balances the pressure of the liquid and prevents liquid from flowing into the gap. Increasing the pressure increases the curvature of the meniscus and expands the contact area between liquid and side walls of the post. The meniscus, which is still pinned to the top and bottom walls, starts to curve and move forward to compensate for the increased pressure. Further increase in the pressure results in the complete progress of the meniscus until it is pinned at the end of the gap. The same trend in the advancement of the meniscus by increasing the liquid pressure was supported by simulation results and likewise by experimental results. However, slight differences in the shape and the position of the interface can occur and to visualize these differences a constant contact angle measured by the static sessile drop method was assumed and the sidewall scallop pattern formed in a Deep Reactive Ion Etching (DRIE) process affects the surface flatness of the micropillars, which differs from perfectly flat side walls that are assumed for the numerical simulations. When the pressure reaches a critical value (burst pressure), increasing the curvature (i.e., reducing the radius of curvature) is insufficient to cancel the excess pressure force and the meniscus breaks to allow the liquid to flow into the vapor channel. Use above the critical pressure is undesirable since it eliminates the liquid-vapor interface and therefore is detrimental to the performance of the heat sink device.

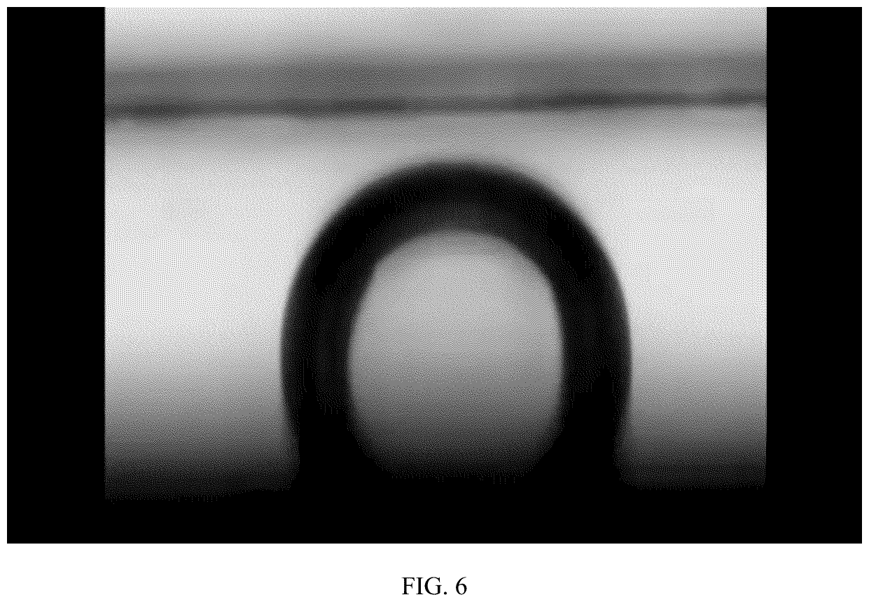

FIG. 6 illustrates a discrete fluid accumulation on a free convection wall having a steep contact line relative to the wall in an adiabatic state. The liquid phase of the heat exchange fluid can have a convexity relative to the vapor-permeable membrane that becomes a receding contact line (more concave) upon phase change to the vapor phase, such that liquid recedes from the contact line and vapor is communicated through the vapor-permeable membrane to be replaced by liquid phase heat exchange fluid thereafter.

In some embodiments, such a heat exchanger can be scaled up to cool a collocated CPU or GPU, such as in a server rack of a server array, e.g., in a data center or the like. In other embodiments, the heat exchanger can be scaled down/miniaturized to be collocated with a single chip or chipset, or a collection of electronic components that are part of a computing device.

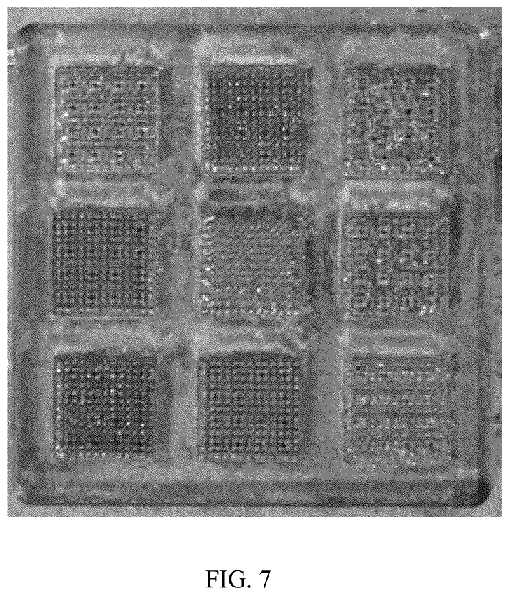

FIG. 7, for example, is a heat map of an electrical component that emits more excess thermal energy/heat in some portions than in others. By using a heat exchange system that includes a vapor-permeable membrane, heat exchange fluid can be used at different rates by different portions of the heat exchange system or by different heat exchangers collocated at the different portions of the chip/chipset, computing device, rack, server array, etc. The differing use is controlled by vapor generation, which is based on heat emitted, such that a mass flow controller is not needed to control how much liquid phase heat exchange fluid is communicated to which portion of a collocated computing device/array. Instead, the vapor is quickly communicated through the vapor-permeable membrane, leaving a volume in the heat exchanger to be filled by liquid phase heat exchanger fluid from the upstream supply/reservoir. As long as a somewhat consistent pressure of liquid phase heat exchange fluid is maintained in the system, the upstream supply will replace demand across the various portions of the chip/chipset, computing device, rack, or array based upon heat generation. As such, liquid phase heat exchange fluid supply to each of the heat exchanger(s) will change over time based on changes in vapor phase heat exchange fluid generation in each of the heat exchanger(s) collocated with the chip/chipset, computing device, rack, or array being served by the heat exchanger(s).

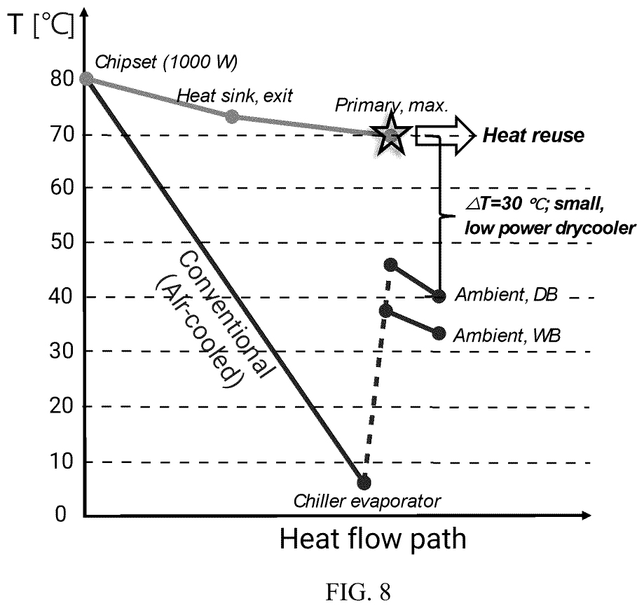

FIG. 8 is a graph illustrating a conventional (air-cooled) heat flow pathway of non-phase-change heat exchangers relative to a phase-change heat exchanger heat flow pathway. As illustrated, the conventional (air-cooled) heat flow pathway starts at a chipset (e.g., a 1,000 W chipset in, e.g., a computing device/server/server rack/server array) that emits waste heat that is absorbed by the conventional heat exchange fluid, raising the temperature to, e.g., about 80° C. To recycle the conventional heat exchange fluid, a conventional air-cooled chiller system is used to reduce the temperature of the conventional heat exchange fluid sufficiently such that the conventional heat exchange fluid can be used again for heat exchange with the chipset. However, since the conventional heat exchange fluid does not undergo a phase change during cooling following heat exchange with the chipset, a large, costly, and energy inefficient conventional chiller and cooling tower system is required to properly recycle the heat exchange fluid and remove the waste heat exchanged between the chipset and the conventional heat exchange fluid in conventional non-phase-change heat exchangers.

Conversely, systems, devices, methods, and approaches described herein can absorb a much larger amount of waste heat from the chipset, which is put to work due to the enthalpy (latent heat) of vaporization (AHvap) of the phase-changing heat exchange fluid. The enthalpy of waste heat from the chipset (at a given pressure) is sufficient to transform at least a portion of the heat exchange fluid from the liquid phase to the vapor phase, thereby storing that enthalpy of waste heat as the vapor state of the heat exchange fluid. However, vaporized heat exchange fluid is, typically, low quality/low value vapor from a cross-process-use or ‘work’ potential perspective. Said otherwise, the hot heat exchange fluid in the vapor phase is typically not of sufficient quality to, e.g., turn a turbine. Vapor quality often refers, at least in part, to the mass fraction in a saturated mixture that is vapor (e.g., at a given partial pressure). From a thermodynamics perspective, a fully saturated vapor has a vapor quality of 100%, while a saturated liquid has a vapor quality of zero.

In some instances, it may be helpful to increase the vapor quality of the hot heat exchange fluid in the vapor phase. In the present disclosure, the use of a vapor-permeable membrane is described for separating vapor-phase heat exchange fluid from liquid-phase heat exchange fluid. There are several benefits of doing such a separation, whether as a batchwise process, semi-continuously, or continuously. For example, by removing only the vapor-phase heat exchange fluid from an admixture of liquid-phase heat exchange fluid and vapor-phase heat exchange fluid, the vapor quality of the vapor-phase heat exchange fluid being communicated out of the phase separation heat exchanger is increased/maximized.

Also, by allowing communication of only vapor-phase heat exchange fluid through a vapor permeable membrane, the concentration of liquid-phase heat exchange fluid remaining on the other side of the vapor-permeable membrane may stay the same or substantially the same over time. This can be helpful because, in phase change heat exchange processes, oftentimes an increasing concentration/volume of vapor-phase heat exchange fluid in or above the remaining liquid-phase heat exchange fluid in a closed space will reduce the rate of phase change of the remaining liquid-phase heat exchange fluid in that closed space.

Further, in phase-change heat exchanging systems, a rate of phase change of a given volume of liquid-phase heat exchange fluid may affect or even control how rapidly/efficiently the enthalpy of waste heat is exchanged between a chipset and the phase-change heat exchanger. As such, by allowing vapor-phase heat exchange fluid to escape through the vapor-permeable membrane while disallowing communication of the liquid-phase heat exchange fluid through the vapor-permeable membrane such that the concentration/volume of vapor-phase heat exchange fluid in/above the liquid-phase heat exchange fluid does not increase appreciably over time, the rate of heat exchange can be increased relative to a scenario in which vapor-phase heat exchange fluid is removed from the liquid-phase heat exchange fluid less effectively/quickly.

During recycling of the vapor-phase heat exchange fluid, as the temperature of the vapor-phase heat exchange fluid drops to the boiling point of the liquid-phase heat exchange fluid, the vapor-phase heat exchange fluid condenses. Due to the phase change of the heat exchange fluid back from a vapor-phase heat exchange fluid to a liquid-phase heat exchange fluid and an associated enthalpy of condensation, the phase change of the vapor-phase heat exchange fluid back to a liquid-phase heat exchange fluid further cools the heat exchange fluid. Conversely, the conventional non-phase-change heat exchange approach requires continuous cooling as the temperature is reduced.

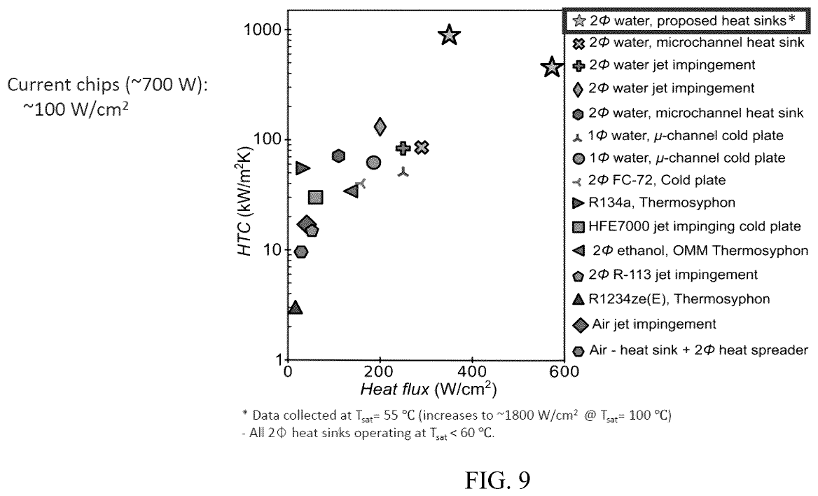

FIG. 9 is a graph of heat transfer coefficient (HTC) in kW/m²K and heat flux (W/cm²) using water as a heat exchange fluid. However, a variety of other heat exchange fluids are contemplated and were evaluated, including FC-72, R134a, HFE70000, ethanol, R-113, R1234ze (e), and air, among others. The heat exchange fluid having the highest HTC and highest heat flux was found to be water, when used in a vapor-permeable membrane heat sink, such as one that uses microchannels. As such, in many of the embodiments disclosed herein, water is used as the heat exchange fluid. In contrast, other of the contemplated and evaluated heat exchange fluids other than water were found to have a relatively low surface tension and many were found to break through the vapor-permeable membrane in liquid form. However, other heat sink membrane material choices, arrangements, configurations, and embodiments were contemplated and examined which may support other heat exchange fluids other than water. As such, the present disclosure is not limited to embodiments in which water is used as the heat exchange fluid.

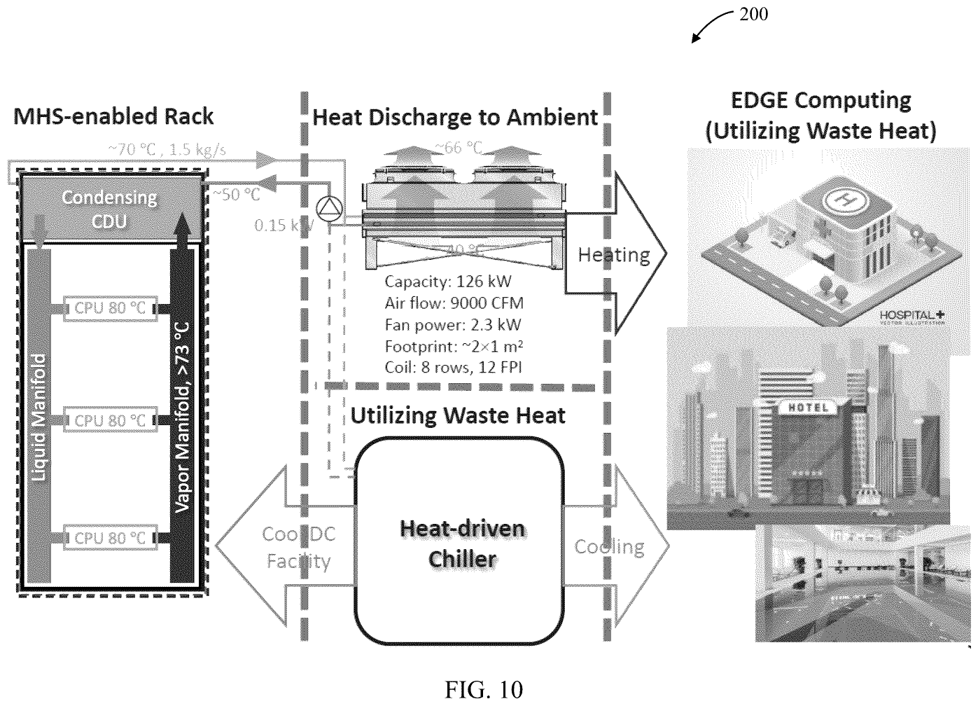

FIG. 10 illustrates a system 200 that can comprise a membrane heat sink (MHS)-enabled server rack, heat exchange system, and edge computing system. In some embodiments, a liquid-heat exchange fluid absorbs heat from a collocated chipset/rack, is routed to a heat-driven chiller where waste heat from the vapor-heat exchange fluid is utilized to drive cooling of the MHS-enabled server rack. In some embodiments, excess heat can be discharged to the ambient air or utilized in system heating in a facility or factor, for example.

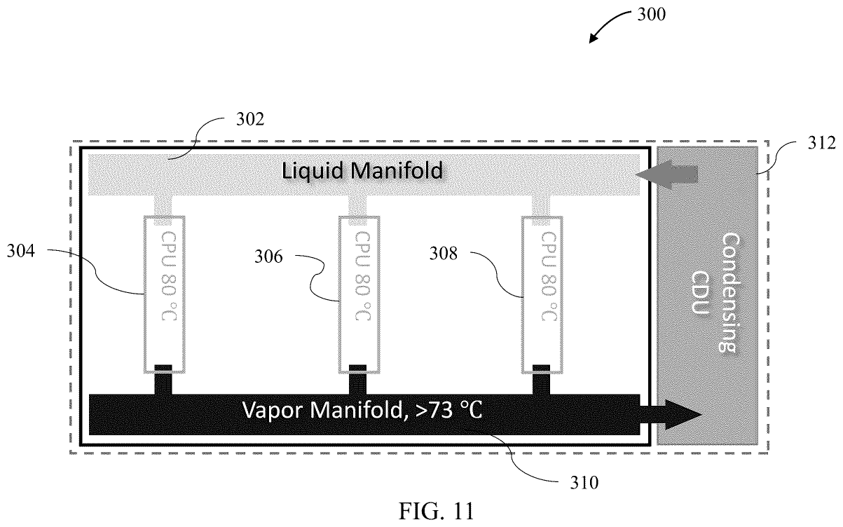

FIG. 11 illustrates a MHS-enabled rack 300. A central liquid manifold can be located upstream of each of a plurality of different CPUs, each independently emitting excess heat. One or more heat exchangers comprising a vapor-permeable membrane can be collocated with each of the CPUs. As liquid phase heat exchange fluid in each heat exchanger absorbs excess heat from the collocated CPU(s), it turns to vapor and the vapor is communicated through the vapor-permeable membrane to a vapor manifold. According to one embodiment, the CPUs may operate at a temperature of about 80° C., and the vapor phase heat exchange fluid formed in the heat exchangers and communicated into the vapor manifold may be at a temperature of about 73° C. The vapor can then be condensed in a condenser unit (CDU) and reused as liquid phase heat exchange liquid supplied to the liquid manifold. Depending on the heat exchange fluid used, the temperature of the vapor phase heat exchange fluid communicated through the vapor-permeable membrane of the heat exchanger(s) may be more or less than about 73° C.

Depending on the application, the excess heat emitted from the CPU(s) or other collocated computing device(s) may be different than in the application shown in FIG. 11, resulting in a CPU operating temperature that is higher or lower than 80° C. Nevertheless, as noted, the rate of liquid phase heat exchange fluid supplied to the liquid manifold can change automatically based on the downstream vapor generation rate, which will change automatically with changes in excess heat generated.

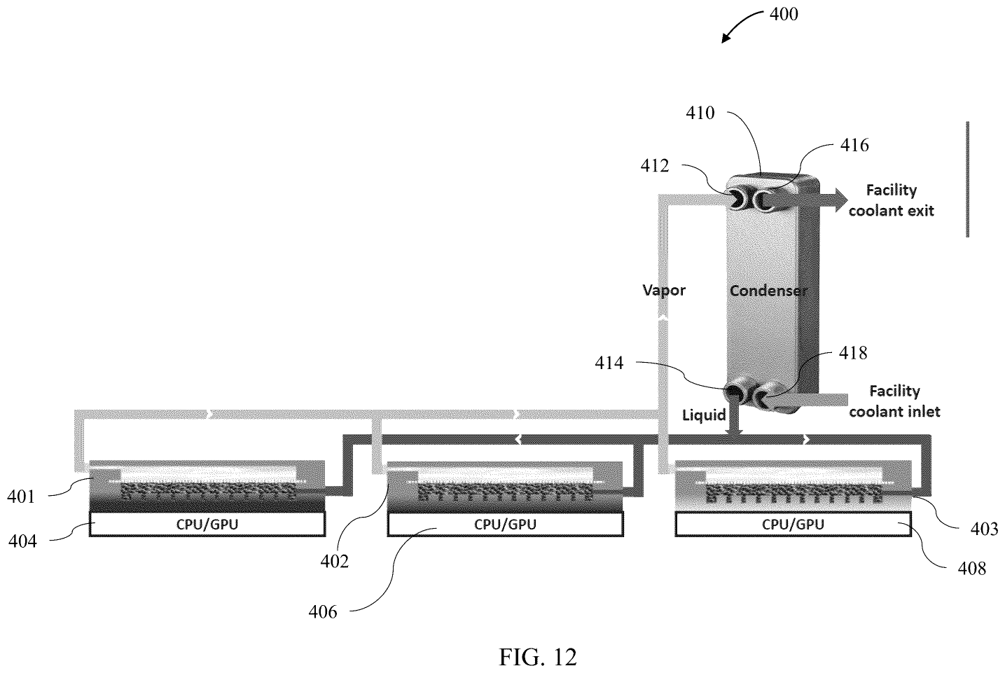

As shown in FIG. 12, in some embodiments a system 400 can be or comprise a phase change heat exchange system. In some embodiments, the system 400 can include one or more heat exchangers, such as a plurality of heat exchangers. In some embodiments, a self-balancing flow system can be provided in which the flow of liquid-heat exchange fluid through the heat exchange system is independent of CPU/GPU heat dissipation. In some embodiments, a plurality of heat exchangers can be collocated with servers/server racks of a server array/chipset. In some instances, the flow of liquid-heat exchange fluid through the heat exchange system can be driven by gravity or a pump. In some embodiments, the liquid-heat exchange fluid can flow from a liquid-heat exchange fluid reservoir to each of the plurality of heat exchangers, whether in parallel or in series. Oftentimes, a mass flow control system is used to balance flow of liquid-heat exchange fluid between the various heat exchangers/heat sinks. This can be important at least because some CPUs/GPUs will generate more waste heat than others such that the rate of phase change of the liquid-heat exchange fluid to the vapor-heat exchange fluid can vary between heat exchangers collocated with the different CPUs/GPUs, and some heat exchangers are located further from the liquid-heat exchange fluid reservoir such that the fluid flow rate will vary between the different collocated heat exchangers.

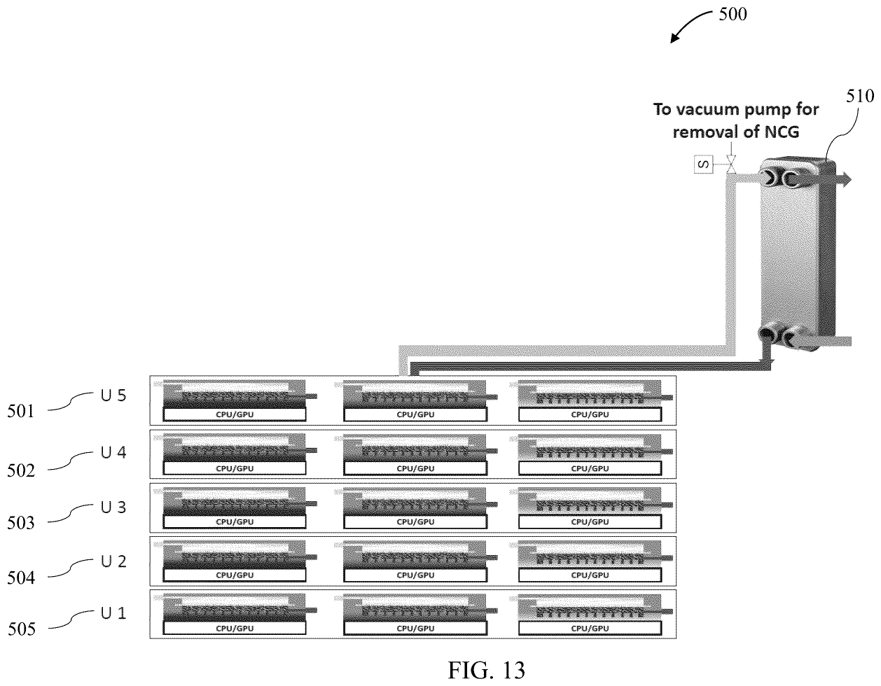

Referring now to FIG. 13, a system 500 can comprise a server array can comprise a plurality of CPUs/GPUs arranged into one or more server racks, such as U 1, U 2, U 3, U 4, and U 5. In some embodiments, a single server rack (e.g., U 1) from among the plurality of server racks can be served (cooled) by a single heat exchanger or a plurality of heat exchangers. In some embodiments, each CPU/GPU in a server rack can be served (cooled) by one or more heat exchangers. The U 1 . . . . U 5 server rack arrangement may be useful because heat exchangers can be collocated vertically beside a vertically arranged server rack/stack or collocated horizontally beside a horizontally arranged server rack/stack, and/or can be arranged in any other suitable manner. In some instances, a heat exchanger may have sufficient heat exchange (cooling) capacity to maintain the CPUs/GPUs in more than one server rack (e.g., U 5 and U 4) within a range of suitable operating temperature simultaneously. In such a circumstance, the single heat exchanger can be collocated between the server racks (e.g., between U 5 and U 4). In certain embodiments, such as when server uptime is a key priority for the operation of the server array/data center, redundant heat exchangers can be collocated with each of the server racks and/or the heat exchanger size/number/arrangement can be such that the heat exchanger system represents an excess cooling capacity relative to the minimum or maximum cooling needs calculated for the server rack/array/data center.

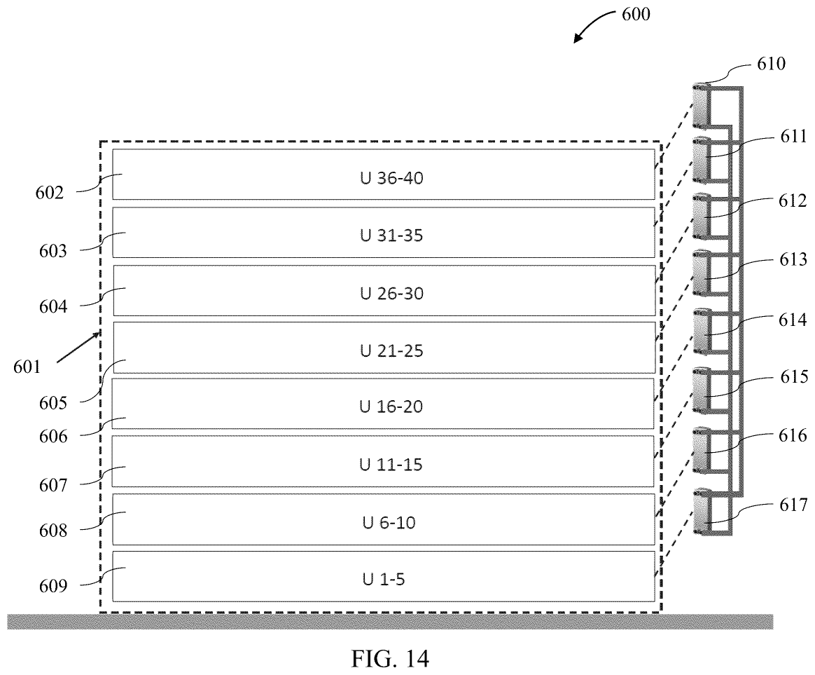

Referring now to FIG. 14, a system 600 can comprise a server rack for a server array can comprise a plurality of stacked (e.g., vertically stacked) server sets, illustrated as U 1-U 5, U 6-U 10, . . . . U 31-U 35, . . . . U 36-U 40. In some embodiments, a single server set (e.g., U 1-U 5) from among the plurality of server sets in the server rack can be served (cooled) by a single heat exchanger or a plurality of heat exchangers. In some embodiments, each CPU/GPU in a server set can be served (cooled) by one or more heat exchangers. The U 1-U 5 . . . . U 36-U 40 server set arrangement may be useful because heat exchangers can be collocated vertically beside a vertically arranged server set in the server rack or collocated horizontally beside a horizontally arranged server set in the server rack, and/or can be arranged in any other suitable manner. In some instances, a heat exchanger may have sufficient heat exchange (cooling) capacity to maintain the CPUs/GPUs in more than one server set (e.g., U 1-U 5 and U 6-U 10) within a range of suitable operating temperature simultaneously. In such a circumstance, the single heat exchanger can be collocated between the server sets (e.g., between U 1-U 5 and U 6-U 10) of the server rack. In certain embodiments, such as when server uptime is a key priority for the operation of the server array/data center, redundant heat exchangers can be collocated with each of the server racks and/or the heat exchanger size/number/arrangement can be such that the heat exchanger system represents an excess cooling capacity relative to the minimum or maximum cooling needs calculated for the server rack/array/data center.

The heat exchanger system and server array in the systems 500, 600 in FIGS. 13 and 14 therefore will experience more ‘uptime’, which is calculated as the percentage of annual operational hours for which a server rack, CPU/GPU, and/or the entire server rack are already pending. Said otherwise, since only portions of the array of CPUs/GPUs are actually grouped into each server rack of the plurality of server racks, a single server rack of CPUs/GPUs can be removed from operation while the server rack/phase change system is evaluated and repaired, without the entire array of CPUs/GPUs being offline during the period of time required for evaluation and repair.

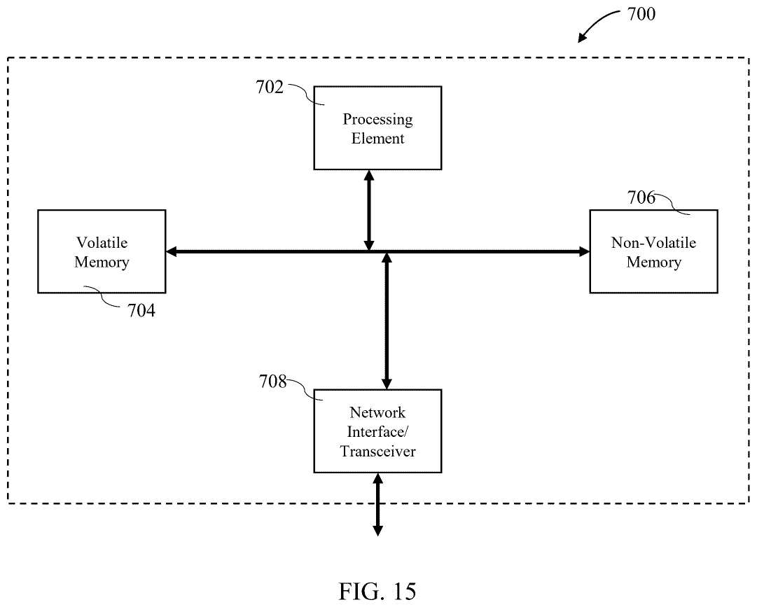

In some embodiments, the communication of liquid-heat exchange fluid to/through the plurality of different heat exchangers can be monitored and/or controlled by a computing device, which may comprise or be comprised in a mass flow control system. In other embodiments, the impermeability of the vapor-permeable membranes in the heat exchanger-fluid exchange approach allows for a constant or substantially constant pressure and/or flow rate of the liquid-heat exchange fluid to be maintained without cycling pumps and motors on and off, without having to actuate valves open and closed repeatedly, and without requiring that the rate of outflow of vapor-heat exchange fluid from each heat exchange fluid be controlled. Examples of such computing devices and entities are described below with regard, e.g., to FIG. 15.

Embodiments of the present disclosure may be implemented in various ways, including as computer program products that comprise articles of manufacture. Such computer program products may include one or more software components including, for example, software objects, methods, data structures, or the like. A software component may be coded in any of a variety of programming languages. An illustrative programming language may be a lower-level programming language, such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid-state drive (SSD), solid state card (SSC), solid state module (SSM), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present invention may also be implemented as methods, apparatus, systems, computing devices, computing entities, and/or the like. As such, embodiments of the present invention may take the form of an apparatus, system, computing device, computing entity, and/or the like executing instructions stored on a computer-readable storage medium to perform certain steps or operations. Thus, embodiments of the present invention may also take the form of an entirely hardware embodiment, an entirely computer program product embodiment, and/or an embodiment that comprises combination of computer program products and hardware performing certain steps or operations.

Embodiments of the present invention are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some embodiments, retrieval, loading, and/or execution may be performed in parallel such that multiple instructions are retrieved, loaded, and/or executed together. Thus, such embodiments can produce specifically-configured machines performing the steps or operations specified in the block diagrams and flowchart illustrations. Accordingly, the block diagrams and flowchart illustrations support various combinations of embodiments for performing the specified instructions, operations, or steps.

FIG. 15 provides a schematic of a computing device 700 that can be configured to monitor and manage a cooling system, such as a vapor-membrane heat sink cooling system (e.g., 200, 300, 400, 500, 600) for, e.g., a server farm. The computing device 700 may comprise one or more processing elements 702, one or more volatile memories 704, one or more non-volatile memories 706, and/or one or more transmitter/receivers 708 (e.g., “transceivers 708”). In some embodiments, the computing device 700 is configured to store one or more computer program products, computer program code, a computer-readable media comprising instructions, and/or the like. In some embodiments, the computing device 700 is configured to determine or receive information regarding a current temperature of one or more portions of, e.g., a server farm, a current pressure within one or more portions of a heat sink cooling system (e.g., 300), and/or other information regarding a current status of the system. Information can be received by the computing device 700 from a manual input, one or more sensors, and/or the like. In some embodiments, the computing device 700 is configured, using any suitable means, to be in wired or wireless communication, such as via the transceivers 708, with one or more motors, valves, actuators, pumps, sensors, and/or the like (not shown) that are configured to cause communication of liquid heat exchange fluid into one or more of the vapor-barrier heat sinks and/or allow communication of vapor heat exchange fluid out of one or more of the vapor-barrier heat sinks. In some embodiments, the computing device 700 can be configured to communicate a set of instructions to one or more motors, actuators, sensors, valves, pumps, and/or the like, for one or a series of actions to be carried out. In some embodiments, the computing device 700 can provide flow rate instructions, e.g., in conjunction with other instructions, to one or more of motors, actuators, sensors, valves, pumps, and/or the like in order for the proper flow rate or discrete volume of liquid heat exchange fluid to be communicated throughout the heat exchange system or to one or more particular vapor-membrane heat exchangers within an array of vapor-membrane heat exchangers, as desired.

In general, the terms computing device, computing entity, computer, entity, device, system, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

As shown in FIG. 15, in one embodiment, the computing device 700 may include or be in communication with one or more processing elements 702 (also referred to as processors, processing circuitry, and/or similar terms used herein interchangeably) that communicate with other elements within the computing device 700 via a bus, for example. As will be understood, the processing element 702 may be embodied in a number of different ways. For example, the processing element 702 may be embodied as one or more complex programmable logic devices (CPLDs), microprocessors, multi-core processors, coprocessing entities, application-specific instruction-set processors (ASIPs), microcontrollers, and/or controllers. Further, the processing element 702 may be embodied as one or more other processing devices or circuitry. The term circuitry may refer to an entirely hardware embodiment or a combination of hardware and computer program products. Thus, the processing element 702 may be embodied as integrated circuits, application specific integrated circuits (ASICs), field programmable gate arrays (FPGAs), programmable logic arrays (PLAs), hardware accelerators, other circuitry, and/or the like. As will therefore be understood, the processing element 702 may be configured for a particular use or configured to execute instructions stored in volatile or non-volatile media or otherwise accessible to the processing element 702. As such, whether configured by hardware or computer program products, or by a combination thereof, the processing element 702 may be capable of performing steps or operations according to embodiments of the present invention when configured accordingly.

In one embodiment, the computing device 700 may further include or be in communication with non-volatile media (also referred to as non-volatile storage, memory, memory storage, memory circuitry, and/or similar terms used herein interchangeably). In one embodiment, the non-volatile storage or memory may include the one or more non-volatile memories 706, including but not limited to hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. As will be recognized, the non-volatile storage or memory media may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

In one embodiment, the computing device 700 may further include or be in communication with volatile media (also referred to as volatile storage, memory, memory storage, memory circuitry, and/or similar terms used herein interchangeably). In one embodiment, the volatile storage or memory may also include one or more volatile memories 706, including but not limited to RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, the processing element 702. Thus, the databases, database instances, database management systems, data, applications, programs, program modules, scripts, source code, object code, byte code, compiled code, interpreted code, machine code, executable instructions, and/or the like may be used to control certain aspects of the operation of the computing device 700 with the assistance of the processing element 702 and operating system.

In some embodiments, the computing device 700 may also include one or more network interfaces, such as a transceiver 708 for communicating with various computing entities, such as by communicating data, content, information, and/or similar terms used herein interchangeably that can be transmitted, received, operated on, processed, displayed, stored, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing device 700 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

Although not shown, the computing device 700 may include or be in communication with one or more input elements, such as a keyboard input, a mouse input, a touch screen/display input, motion input, movement input, audio input, pointing device input, joystick input, keypad input, and/or the like. The computing device 700 may also include or be in communication with one or more output elements (not shown), such as audio output, video output, screen/display output, motion output, movement output, and/or the like.

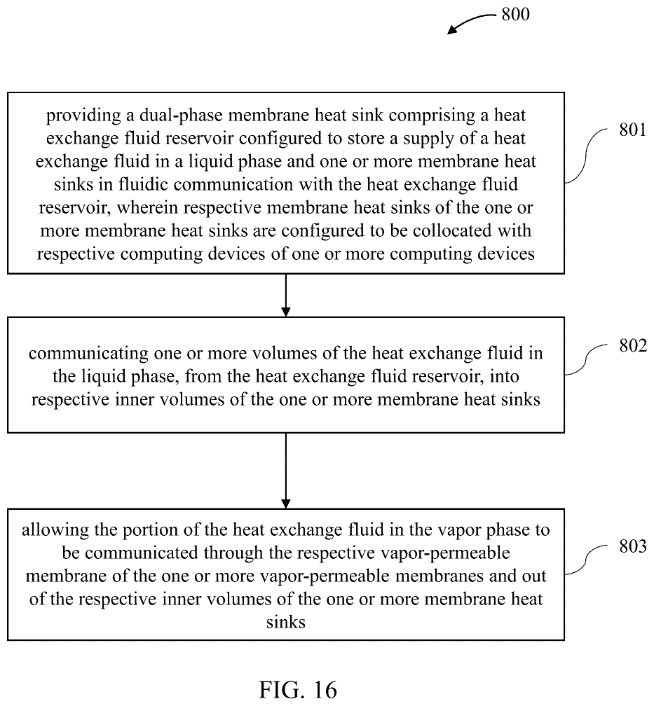

Referring now to FIG. 16, a method 800 for implementing membrane-based phase change heat sinks for cooling collocated computing devices is illustrated. The method 800 can be carried out by means, such as by the processing element 702 executing one or more instructions or program codes stored on a memory (e.g., 706). In some embodiments, the method 800 can comprise: providing a dual-phase membrane heat sink comprising a heat exchange fluid reservoir configured to store a supply of a heat exchange fluid in a liquid phase and one or more membrane heat sinks in fluidic communication with the heat exchange fluid reservoir, wherein respective membrane heat sinks of the one or more membrane heat sinks are configured to be collocated with respective computing devices of one or more computing devices, at 801. In some embodiments, the method 800 can further comprise: communicating one or more volumes of the heat exchange fluid in the liquid phase, from the heat exchange fluid reservoir, into respective inner volumes of the one or more membrane heat sinks, at 802. In some embodiments, heat conducted from the one or more computing devices and into the respective inner volumes of the one or more membrane heat sinks causes a portion of the heat exchange fluid in the liquid phase in the respective inner volumes of the one or more membrane heat sinks to undergo a phase change from the heat exchange fluid in the liquid phase to heat exchange fluid in a vapor phase. In some embodiments, respective membrane heat sinks of the one or more membrane heat sinks comprise a vapor-permeable membrane that is configured to allow communication therethrough of the portion of the heat exchange fluid in the vapor phase while disallowing communication therethrough of a remaining portion of the heat exchange fluid in the liquid phase. In some embodiments, the method 800 can further comprise: allowing the portion of the heat exchange fluid in the vapor phase to be communicated through the respective vapor-permeable membrane of the one or more vapor-permeable membranes and out of the respective inner volumes of the one or more membrane heat sinks, at 803.

In some embodiments, the respective membrane heat sinks of the one or more membrane heat sinks comprise: a bottom structure defining a first portion of an inner volume of the membrane heat sink, the bottom structure comprising a liquid inlet being configured to allow a volume of the heat exchange fluid in the liquid phase to be communicated from the heat exchange fluid reservoir into the first portion of the inner volume of the membrane heat sink. In some embodiments, the respective membrane heat sinks of the one or more membrane heat sinks can further comprise: a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink. In some embodiments, the respective membrane heat sinks of the one or more membrane heat sinks can further comprise: a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure.

In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes phase change of an amount equal to the volume of the incoming heat exchange fluid from the liquid phase to a vapor phase. In some embodiments, the vapor-permeable membrane is configured to allow the portion of the volume of the heat exchange fluid that changes phase from the liquid to vapor to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the dual-phase membrane heat sink can further comprise: a heat exchange fluid recovery unit configured to cause a second phase change of the volume of the heat exchange fluid in the vapor phase back to the liquid phase. In some embodiments, the dual-phase membrane heat sink can further comprise: a heat exchange fluid distribution system in fluidic communication with the heat exchange fluid reservoir and the plurality of membrane heat sinks. In some embodiments, the heat exchange fluid distribution system is configured to maintain the heat exchange fluid within the heat exchange fluid distribution system at a hydrostatic pressure within a predetermined range.

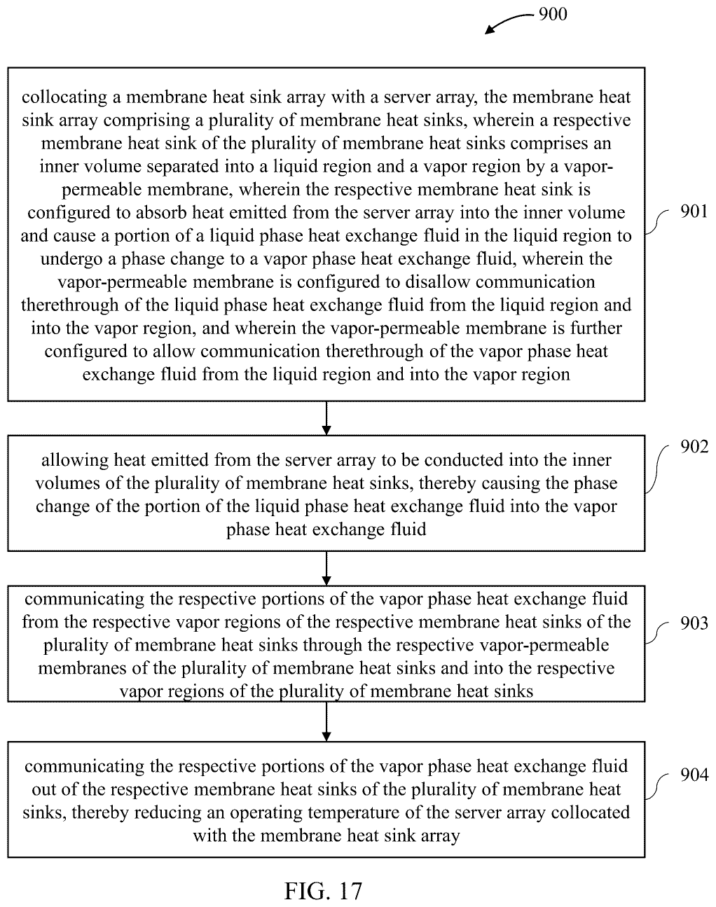

Referring now to FIG. 17, a method 900 for implementing membrane-based phase change heat sinks for cooling collocated computing devices is illustrated. The method 900 can be carried out by means, such as by the processing element 702 executing one or more instructions or program codes stored on a memory (e.g., 706). In some embodiments, the method 900 can comprise: collocating a membrane heat sink array with a server array, the membrane heat sink array comprising a plurality of membrane heat sinks, wherein a respective membrane heat sink of the plurality of membrane heat sinks comprises an inner volume separated into a liquid region and a vapor region by a vapor-permeable membrane, wherein the respective membrane heat sink is configured to absorb heat emitted from the server array into the inner volume and cause a portion of a liquid phase heat exchange fluid in the liquid region to undergo a phase change to a vapor phase heat exchange fluid, wherein the vapor-permeable membrane is configured to disallow communication therethrough of the liquid phase heat exchange fluid from the liquid region and into the vapor region, and wherein the vapor-permeable membrane is further configured to allow communication therethrough of the vapor phase heat exchange fluid from the liquid region and into the vapor region, at 901.

In some embodiments, the method 900 can further comprise: allowing heat emitted from the server array to be conducted into the inner volumes of the plurality of membrane heat sinks, thereby causing the phase change of the portion of the liquid phase heat exchange fluid into the vapor phase heat exchange fluid, at 902. In some embodiments, the method 900 can further comprise: communicating the respective portions of the vapor phase heat exchange fluid from the respective vapor regions of the respective membrane heat sinks of the plurality of membrane heat sinks through the respective vapor-permeable membranes of the plurality of membrane heat sinks and into the respective vapor regions of the plurality of membrane heat sinks, at 903. In some embodiments, the method 900 can further comprise: communicating the respective portions of the vapor phase heat exchange fluid out of the respective membrane heat sinks of the plurality of membrane heat sinks, thereby reducing an operating temperature of the server array collocated with the membrane heat sink array, at 904.

In some embodiments, the server array comprises a plurality of computing devices arranged according to one or more server racks. In some embodiments, each server rack of the one or more server racks comprises one or more of the plurality of computing devices. In some embodiments, the method 900 can further comprise: providing a heat exchange fluid reservoir fluidically coupled to the plurality of membrane heat sinks. In some embodiments, the heat exchange fluid reservoir is configured to supply a plurality of volumes of the liquid phase heat exchange fluid to respective liquid regions within respective ones of the plurality of membrane heat sinks.

In some embodiments, each respective membrane heat sink from among the plurality of membrane heat sinks can comprise: a bottom structure defining a first portion of an inner volume of the membrane heat sink, the bottom structure comprising a liquid inlet at least partially defined by an aperture through the bottom structure, the liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure.

In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes a phase change of at least a portion of the volume of the heat exchange fluid from the liquid phase to a vapor phase. In some embodiments, the vapor-permeable membrane is configured to allow the portion of the volume of the heat exchange fluid that changes phase from liquid to vapor to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the method 900 can further comprise: providing a heat exchange fluid recovery unit configured to cause a second phase change of the vapor phase heat exchange fluid, once it is communicated out of the plurality of membrane heat sinks, back to the liquid phase heat exchange fluid. In some embodiments, the method 900 can further comprise: providing a heat exchange fluid distribution system in fluidic communication with the heat exchange fluid reservoir and the plurality of membrane heat exchangers. In some embodiments, the heat exchange fluid distribution system is configured to maintain the heat exchange fluid within the heat exchange fluid distribution system at a hydrostatic pressure within a predetermined range. In some embodiments, the heat exchange fluid reservoir is further configured to cause a second phase change of the volume of the heat exchange fluid in the vapor phase back to the liquid phase. In some embodiments, excess heat removed from the heat exchange fluid reservoir is transferred to a server cluster primary loop of the data center and heat exchange fluid converted back to the liquid phase is transferred back to a primary liquid cooling loop of the data center.

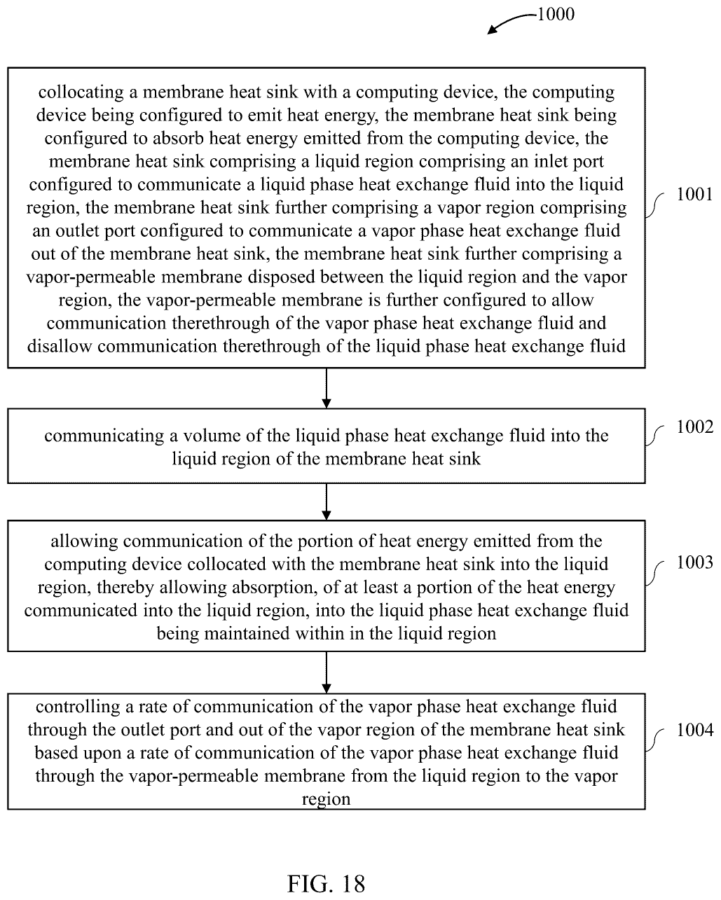

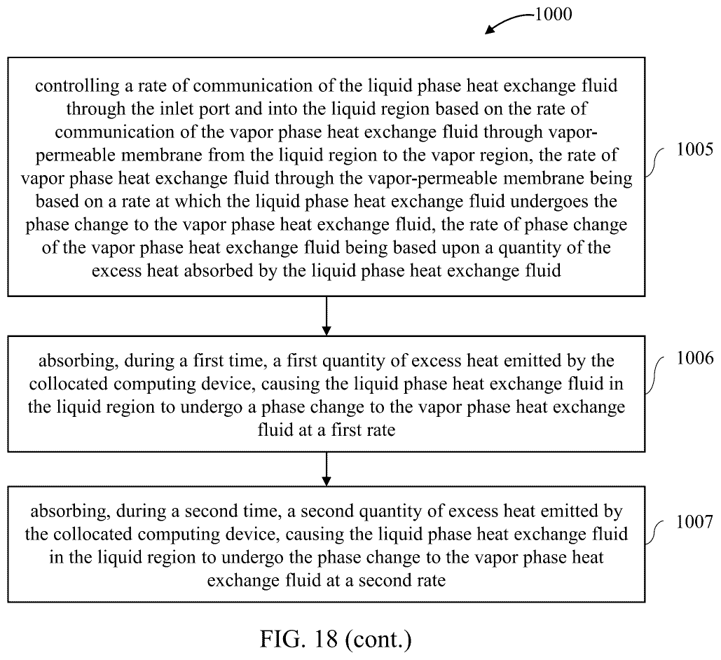

Referring now to FIG. 18, a method 1000 for implementing membrane-based phase change heat sinks for cooling collocated computing devices is illustrated. In some embodiments, the collocated computing devices can comprise devices or systems, such as servers, server racks, server arrays, or data centers. The method 1000 can be carried out by means, such as by the processing element 702 executing one or more instructions or program codes stored on a memory (e.g., 706). In some embodiments, the method 1000 can comprise: collocating a membrane heat sink with a computing device, the computing device being configured to emit heat energy, the membrane heat sink being configured to absorb heat energy emitted from the computing device, the membrane heat sink comprising a liquid region comprising an inlet port configured to communicate a liquid phase heat exchange fluid into the liquid region, the membrane heat sink further comprising a vapor region comprising an outlet port configured to communicate a vapor phase heat exchange fluid out of the membrane heat sink, the membrane heat sink further comprising a vapor-permeable membrane disposed between the liquid region and the vapor region, the vapor-permeable membrane is further configured to allow communication therethrough of the vapor phase heat exchange fluid and disallow communication therethrough of the liquid phase heat exchange fluid, at 1001. In some embodiments, the method 1000 can further comprise: communicating a volume of the liquid phase heat exchange fluid into the liquid region of the membrane heat sink, at 1102. In some embodiments, the method 1000 can further comprise: allowing communication of the portion of heat energy emitted from the computing device collocated with the membrane heat sink into the liquid region, thereby allowing absorption, of at least a portion of the heat energy communicated into the liquid region, into the liquid phase heat exchange fluid being maintained within in the liquid region, at 1003. In some embodiments, the method 1000 can further comprise: controlling a rate of communication of the vapor phase heat exchange fluid through the outlet port and out of the vapor region of the membrane heat sink based upon a rate of communication of the vapor phase heat exchange fluid through the vapor-permeable membrane from the liquid region to the vapor region, at 1004.

In some embodiments, the method 1000 can further comprise: controlling a rate of communication of the liquid phase heat exchange fluid through the inlet port and into the liquid region based on the rate of communication of the vapor phase heat exchange fluid through vapor-permeable membrane from the liquid region to the vapor region, the rate of vapor phase heat exchange fluid through the vapor-permeable membrane being based on a rate at which the liquid phase heat exchange fluid undergoes the phase change to the vapor phase heat exchange fluid, the rate of phase change of the vapor phase heat exchange fluid being based upon a quantity of the excess heat absorbed by the liquid phase heat exchange fluid, at 1005. In some embodiments, the method 1000 can further comprise: absorbing, during a first time, a first quantity of excess heat emitted by the collocated computing device, causing the liquid phase heat exchange fluid in the liquid region to undergo a phase change to the vapor phase heat exchange fluid at a first rate, at 1006. In some embodiments, the method 1000 can further comprise: absorbing, during a second time, a second quantity of excess heat emitted by the collocated computing device, causing the liquid phase heat exchange fluid in the liquid region to undergo the phase change to the vapor phase heat exchange fluid at a second rate, at 1007.

In some embodiments, the volume of the liquid phase heat exchange fluid that undergoes the phase change to the vapor phase heat exchange fluid during the second tie is based upon a second quantity of the excess heat absorbed by the liquid phase heat exchange fluid during the second time.

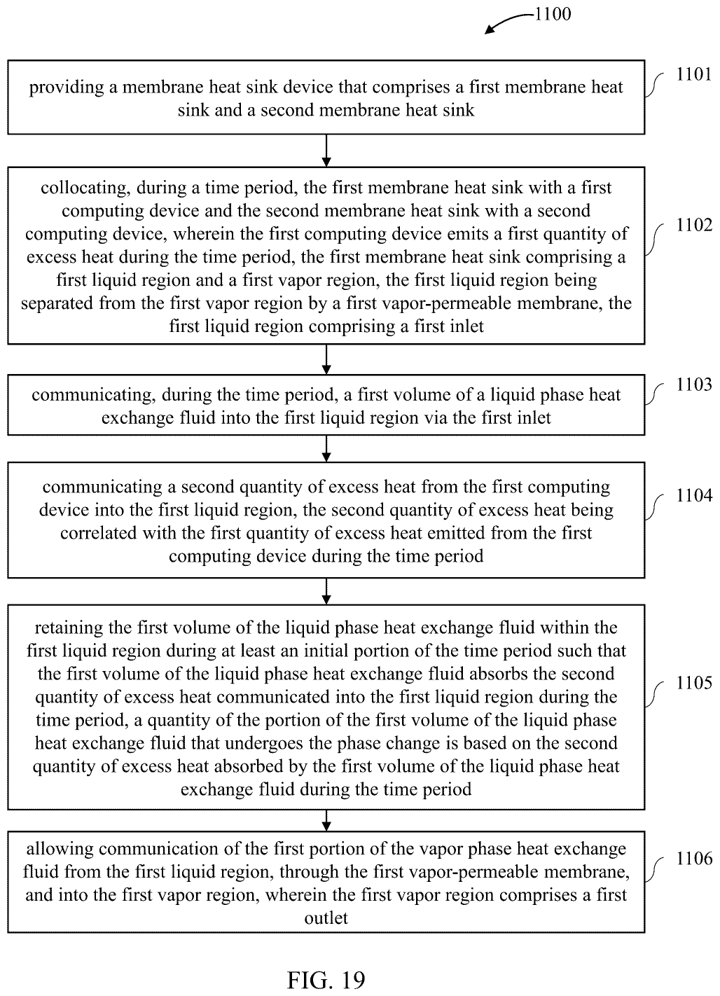

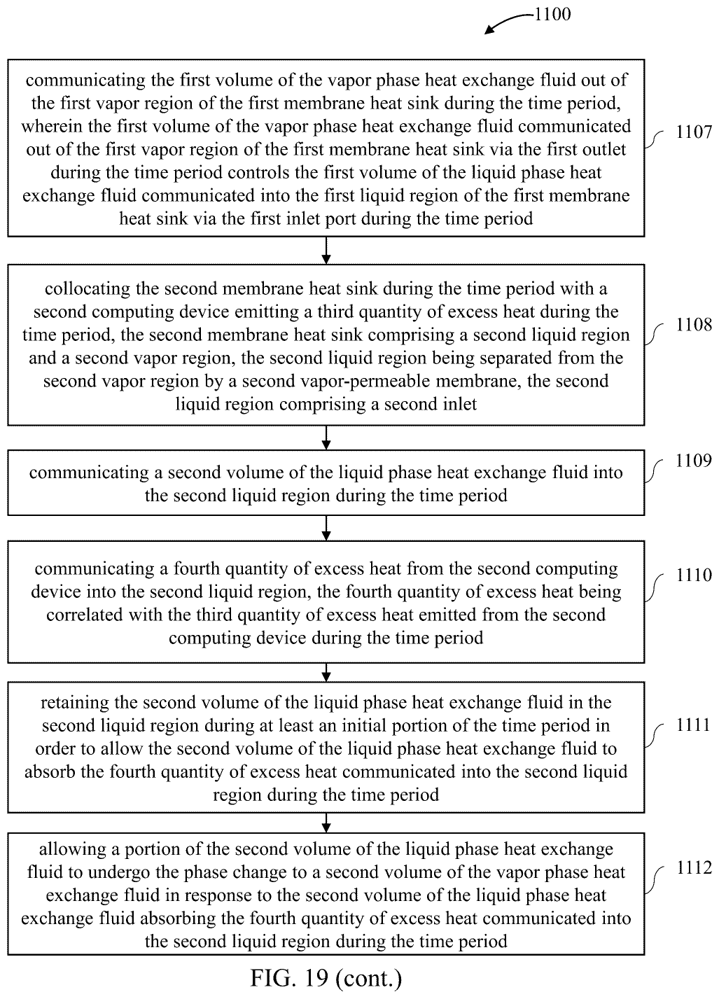

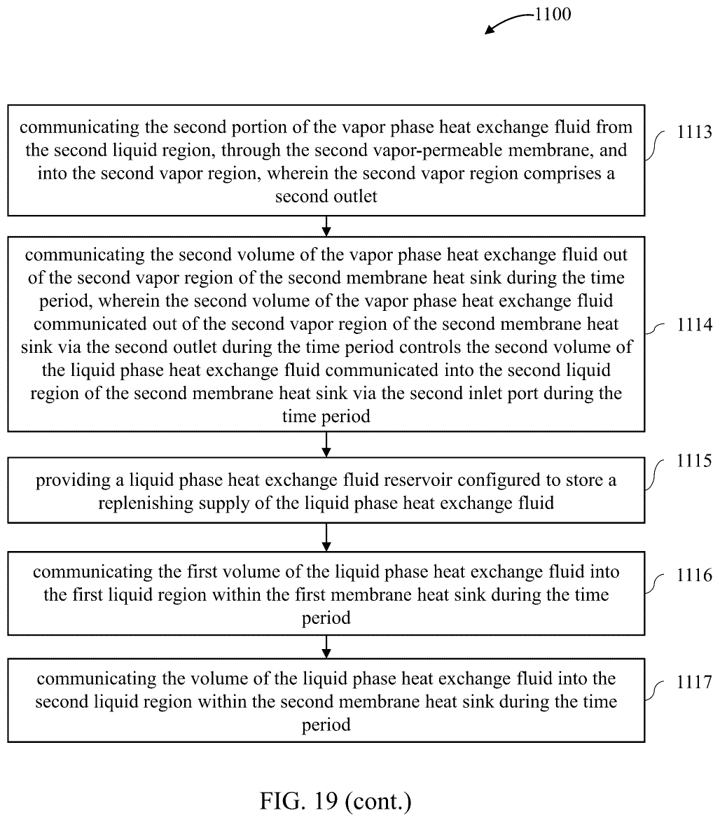

Referring now to FIG. 19, a method 1100 for implementing membrane-based phase change heat sinks for cooling collocated computing devices is illustrated. In some embodiments, the collocated computing devices can comprise devices or systems, such as servers, server racks, server arrays, or data centers. The method 1100 can be carried out by means, such as by the processing element 702 executing one or more instructions or program codes stored on a memory (e.g., 706). In some embodiments, the method 1100 can comprise: providing a membrane heat sink device that comprises a first membrane heat sink and a second membrane heat sink, at 1101. In some embodiments, the method 1100 can further comprise: collocating, during a time period, the first membrane heat sink with a first computing device and the second membrane heat sink with a second computing device, wherein the first computing device emits a first quantity of excess heat during the time period, the first membrane heat sink comprising a first liquid region and a first vapor region, the first liquid region being separated from the first vapor region by a first vapor-permeable membrane, the first liquid region comprising a first inlet, at 1102.

In some embodiments, the method 1100 can further comprise: communicating, during the time period, a first volume of a liquid phase heat exchange fluid into the first liquid region via the first inlet, at 1103. In some embodiments, the method 1100 can further comprise: communicating a second quantity of excess heat from the first computing device into the first liquid region, the second quantity of excess heat being correlated with the first quantity of excess heat emitted from the first computing device during the time period, at 1104. In some embodiments, the method 1100 can further comprise: retaining the first volume of the liquid phase heat exchange fluid within the first liquid region during at least an initial portion of the time period such that the first volume of the liquid phase heat exchange fluid absorbs the second quantity of excess heat communicated into the first liquid region during the time period, a quantity of the portion of the first volume of the liquid phase heat exchange fluid that undergoes the phase change is based on the second quantity of excess heat absorbed by the first volume of the liquid phase heat exchange fluid during the time period, at 1105. In some embodiments, the method 1100 can further comprise: allowing communication of the first portion of the vapor phase heat exchange fluid from the first liquid region, through the first vapor-permeable membrane, and into the first vapor region, wherein the first vapor region comprises a first outlet, at 1106.

In some embodiments, the method 1100 can further comprise: communicating the first volume of the vapor phase heat exchange fluid out of the first vapor region of the first membrane heat sink during the time period, wherein the first volume of the vapor phase heat exchange fluid communicated out of the first vapor region of the first membrane heat sink via the first outlet during the time period controls the first volume of the liquid phase heat exchange fluid communicated into the first liquid region of the first membrane heat sink via the first inlet port during the time period, at 1107. In some embodiments, the method 1100 can further comprise: collocating the second membrane heat sink during the time period with a second computing device emitting a third quantity of excess heat during the time period, the second membrane heat sink comprising a second liquid region and a second vapor region, the second liquid region being separated from the second vapor region by a second vapor-permeable membrane, the second liquid region comprising a second inlet, at 1108. In some embodiments, the method 1100 can further comprise: communicating a second volume of the liquid phase heat exchange fluid into the second liquid region during the time period, at 1109. In some embodiments, the method 1100 can further comprise: communicating a fourth quantity of excess heat from the second computing device into the second liquid region, the fourth quantity of excess heat being correlated with the third quantity of excess heat emitted from the second computing device during the time period, at 1110. In some embodiments, the method 1100 can further comprise: retaining the second volume of the liquid phase heat exchange fluid in the second liquid region during at least an initial portion of the time period in order to allow the second volume of the liquid phase heat exchange fluid to absorb the fourth quantity of excess heat communicated into the second liquid region during the time period, at 1111. In some embodiments, the method 1100 can further comprise: allowing a portion of the second volume of the liquid phase heat exchange fluid to undergo the phase change to a second volume of the vapor phase heat exchange fluid in response to the second volume of the liquid phase heat exchange fluid absorbing the fourth quantity of excess heat communicated into the second liquid region during the time period, at 1112.

In some embodiments, the method 1100 can further comprise: communicating the second portion of the vapor phase heat exchange fluid from the second liquid region, through the second vapor-permeable membrane, and into the second vapor region, wherein the second vapor region comprises a second outlet, at 1113. In some embodiments, the method 1100 can further comprise: communicating the second volume of the vapor phase heat exchange fluid out of the second vapor region of the second membrane heat sink during the time period, wherein the second volume of the vapor phase heat exchange fluid communicated out of the second vapor region of the second membrane heat sink via the second outlet during the time period controls the second volume of the liquid phase heat exchange fluid communicated into the second liquid region of the second membrane heat sink via the second inlet port during the time period, at 1114. In some embodiments, the method 1100 can further comprise: providing a liquid phase heat exchange fluid reservoir configured to store a replenishing supply of the liquid phase heat exchange fluid, at 1115. In some embodiments, the method 1100 can further comprise: communicating the first volume of the liquid phase heat exchange fluid into the first liquid region within the first membrane heat sink during the time period, at 1116. In some embodiments, the method 1100 can further comprise: communicating the volume of the liquid phase heat exchange fluid into the second liquid region within the second membrane heat sink during the time period, at 1117.

In some embodiments, the method 1100 can, optionally, further comprise providing a liquid phase heat exchange fluid reservoir configured to store a replenishing supply of the liquid phase heat exchange fluid (not shown). In some embodiments, the method 1100 can, optionally, further comprise communicating the first volume of the liquid phase heat exchange fluid into the first liquid region within the first membrane heat sink during the time period (not shown). In some embodiments, the method 1100 can, optionally, further comprise communicating the second volume of the liquid phase heat exchange fluid into the second liquid region within the second membrane heat sink during the time period (not shown).

In some embodiments, the method 1100 can, optionally, further comprise providing a vapor phase heat exchange fluid recovery unit (not shown). In some embodiments, the method 1100 can, optionally, further comprise communicating the first and second volumes of the vapor phase heat exchange fluid into the vapor phase heat exchange fluid recovery unit (not shown). In some embodiments, the method 1100 can, optionally, further comprise causing a second phase change of the first and second volumes of the vapor phase heat exchange fluid in the vapor phase heat exchange fluid recovery unit back to liquid phase heat exchange fluid (not shown).

In some embodiments, the method 1100 can, optionally, further comprise providing a liquid phase heat exchange fluid distribution system in fluidic communication with the liquid phase heat exchange fluid reservoir, the first membrane heat sink, and the second membrane heat sink (not shown). In some embodiments, the method 1100 can, optionally, further comprise maintaining, using the liquid phase heat exchange fluid distribution system, a hydrostatic pressure of all liquid phase heat exchange fluid within the liquid phase heat exchange fluid distribution system within a predetermined hydrostatic pressure range (not shown).

In some embodiments, the liquid phase heat exchange fluid can comprise any suitable fluid, e.g., ranging from water through hydrofluorocarbon refrigerants, for example: trifluoromethane, difluoromethane, fluoromethane, pentafluoroethane, pentafluorodimethyl ether, 1,1,2,2-tetrafluoroethane, 1,1,1,2-tetrafluoroethane, bis(difluoromethyl) ether, 1,1,2-trifluoroethane, 1,1,1-trifluoroethane, methyl trifluoromethyl ether, 2,2,2-trifluoroethyl methyl ether, 1,2-difluoroethane, 1,1-difluoroethane, fluoroethane, 1,1,2,2,3,3,3-heptafluoropropane, trifluoromethyl 1,1,2,2-tetrafluoroethyl ether, 1,1,1,2,3,3,3-heptafluoropropane, trifluoromethyl 1,2,2,2-tetrafluoroethyl ether, 1,1,1,2,2,3-hexafluoropropane, 1,1,1,2,3,3-hexafluoropropane, 1,1,1,3,3,3-hexafluoropropane, 1,2,2,2-tetrafluoroethyl difluoromethyl ether, hexafluoropropane, 1,1,2,2,3-pentafluoropropane, pentafluoropropane, 1,1,2,3,3-pentafluoropropane, 1,1,1,2,3-pentafluoropropane, 1,1,1,3,3-pentafluoropropane, methyl pentafluoroethyl ether, difluoromethyl 2,2,2-trifluoroethyl ether, difluoromethyl 1,1,2-trifluoroethyl ether, 1,1,2,2-tetrafluoropropane, methyl 1,1,2,2-tetrafluoroethyl ether, trifluoropropane, or any fluorocarbon or hydrofluorocarbon. In general, flammable fluids are avoided, but there is no limitation to the fluid as long as the boiling point is about 100° C. or less. In some embodiments, the membrane is a nanostructured membrane that is of a hydrophobic material. Hydrophobic materials are defined as any material upon which a water droplet displays a contact angle of, e.g., at least 90 degrees. For example, an exemplary membrane is a polytetrafluoroethylene (PTFE) nanofiber membrane. Any other material can be used as long as the material is hydrophobic as defined by the water contact angle.

In some embodiments, the membrane is supported by fins, which are supports that extend perpendicularly from the base of the heat sink in the active area of the heat sink, where the base is the surface through which heat is transferred from the microelectronic device to the fluid through the exposed base surface and the surfaces of the fins. The fins can have any geometry that allows the flow of a refrigerant between the fins. The fins permit fluid to flow from multiple sides and are not restricted to flow from one dimension, as is common to current microchannel heat sink devices. The fins have dimensions of about 1 to about 200 micrometer in cross-section and have a height that is equal to or greater than the cross-section and can be about 250 micrometers or less. The fins can be of any shape; for example, the fins can be square pillars in shape, cylinders in shape, or any polygon in shape that permits relative unimpeded flow of fluid into the active area. The fins can be patterned by voids or other features on their surfaces to increase surface area, promote nucleation of vapor, or perform any other desirable action. The fins support the membrane and can transfer heat from the base of the heat sink. The heat sink base and fins can be selected independently from any material with thermal conductivity greater than about 10 W/m·K. In some embodiments, the base and the fins are of the same material. In an exemplary embodiment, the heat sink can be made with or comprise silicon having a thermal conductivity of 149 W/m·K. In some embodiments, the heat sink can be made with or comprise a copper-comprising or a copper-based material having a thermal conductivity of about 400 W/m·K. Other materials that can be employed include metals and composites that include a filler of high thermal conductivity, such as metal fibers, carbon nanotubes, or graphene flakes.

In some embodiments, the central portion of the heat sink is the active area that contains the fins. The active area is surrounded by trenches that fill with fluid and supply the fluid to the active area. The trenches can have the same depth as the fins, sharing a common base as that of the active area, or can be of other depths that promote regular even flow of fluid into the active area. The trenches can contain a volume of fluid that is similar to the volume of fluid that can be contained within the active area. For example, the trenches can contain about 70 to about 150 percent of the fluid volume as the active area. The active area need not be square; instead, the active area can be any suitable shape or arrangement of shapes, such as circular or any other geometry. Generally, although not necessarily, the geometry of the active area is a regular geometry, for example, a regular polygon, and generally, but not necessarily, the trenches are situated regularly about the active area.

In some embodiments, the heat sink can be configured such that an active area in the inner volume of the heat exchange directs the vapor fluid to a condenser where the vapor reverts to a liquid for reintroduction into the heat sink. The condenser is maintained at a temperature desirable to return the vapor to the liquid phase at a temperature equal to or below the temperature of the liquid introduced to the heat sink. Depending on the fluid employed and the pressure maintained within the system, the temperature can be sub-ambient to temperatures higher than the boiling point of the fluid at ambient pressures. The pressures can be sub-ambient to multiple atmospheres, depending upon the heat sink material's ability to safely maintain that pressure, where, for example, for a metal heat sink, pressures in excess of 100 psi are possible. The liquid fluid can return to the heat sink from the condenser by the force of gravity or as provided by a pump. The condenser or any fluid reservoir downstream of the condenser can be used to feed one or more heat sinks.

The heat sink can provide vastly superior performance to that of state of the art heat sinks for microelectronic devices. In some embodiments, heat flux can be a function of superheat temperature and compared to prior art heat sinks reported in the literature. The trend indicates that the heat flux is a strong function of the surface superheat temperature, which, unlike that displayed by the majority of prior art devices that employ uniform micro channels, does not approach a plateau heat flux over the range of temperatures examined. Although not to be limited by mechanism, the performance of the heat sink somewhat resembles that of impingement cooling systems.

In comparison to other state of the art heat sinks, described herein are heat sinks/heat exchanger systems for which a superior heat flux is achieved at a much lower mass flux, being more than an order of magnitude lower than that previously reported. As the system has an unprecedented 100% vapor quality, a dramatically higher heat transfer coefficient is achievable. When compared to the previous maximum vapor quality device, the heat transfer coefficient is about an order of magnitude higher for the heat sink, according to an embodiment described herein.

Described herein are membrane-based heat sinks and membrane-based heat exchangers, as well as servers, server racks, server arrays, and data centers using the same to cool collocated computing devices therein/thereof. For example, a dual-phase membrane heat sink system can comprise a heat exchange fluid reservoir configured to store a supply of a heat exchange fluid in a liquid phase; and a plurality of membrane heat sinks in fluidic communication with the heat exchange fluid reservoir, wherein respective membrane heat sinks of the plurality of membrane heat sinks are configured to be collocated with respective computing devices of a plurality of computing devices. In some embodiments, each of the plurality of membrane heat sinks comprise: a bottom structure defining a first portion of an inner volume of the membrane heat sink, the bottom structure comprising a liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure.

In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes phase change of an amount equal to the volume of the incoming heat exchange fluid from the liquid phase to a vapor phase. In some embodiments, the vapor-permeable membrane is configured to allow the portion of the volume of the heat exchange fluid that changes phase from the liquid to vapor to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the dual-phase membrane heat sink system further comprises: a heat exchange fluid recovery unit configured to cause a second phase change of the volume of the heat exchange fluid in the vapor phase back to the liquid phase. In some embodiments, the dual-phase membrane heat sink system further comprises: a heat exchange fluid distribution system in fluidic communication with the heat exchange fluid reservoir and the plurality of membrane heat sinks.

In some embodiments, the heat exchange fluid distribution system is configured to maintain the heat exchange fluid within the heat exchange fluid distribution system at a hydrostatic pressure within a predetermined range.

According to another embodiment, a server cluster can be provided that is configured for data storage in a data center, the server cluster comprising: a plurality of computing devices arranged in a plurality of server racks, each server rack of the plurality of server racks comprising two or more of the plurality of computing devices; a heat exchange fluid reservoir configured to store a supply of a heat exchange fluid in a liquid phase; and a plurality of membrane heat sinks in fluidic communication with the heat exchange fluid reservoir, wherein respective membrane heat sinks of the plurality of membrane heat sinks are configured to be collocated with respective computing devices of the plurality of computing devices. In some embodiments, each of the plurality of membrane heat sinks comprise: a bottom structure defining a first portion of an inner volume of the membrane heat sink, the bottom structure comprising a liquid inlet at least partially defined by an aperture through the bottom structure, the liquid inlet being configured to allow a volume of the heat exchange fluid in the liquid phase to be communicated from the heat exchange fluid reservoir into the first portion of the inner volume of the membrane heat sink; a top structure defining a second portion of the inner volume of the membrane heat sink, the top structure comprising a vapor outlet at least partially defined by an aperture through the top structure, the vapor outlet being configured to allow a volume of the heat exchange fluid in a fluid phase to be communicated out of the second portion of the inner volume of the membrane heat sink; and a vapor-permeable membrane interposed between the top structure and the bottom structure, a portion of a first surface of the vapor-permeable membrane being sealably joined to an inside surface of the bottom structure and a portion of a second surface of the vapor-permeable membrane being sealably joined to an inside surface of the top structure. In some embodiments, the bottom structure of each membrane heat sink is configured to allow heat absorption, by the volume of the heat exchange fluid in the liquid phase, from the respective computing devices of the plurality of computing devices collocated therewith. In some embodiments, the heat absorption by the volume of the heat exchange fluid in the liquid phase causes a phase change of at least a portion of the volume of the heat exchange fluid from the liquid phase to a vapor phase. In some embodiments, the vapor-permeable membrane is configured to allow the portion of the volume of the heat exchange fluid that changes phase from liquid to vapor to be communicated therethrough, from the first portion of the inner volume of the membrane heat sink, to the second portion of the inner volume of the membrane heat sink, such that the portion of the heat exchange fluid in the vapor phase is communicated out of the membrane heat sink while the portion of the heat exchange fluid in the liquid phase is disallowed from being communicated out of the membrane heat sink.

In some embodiments, the server cluster further comprises: a heat exchange fluid recovery unit configured to cause a second phase change of the volume of the heat exchange fluid in the vapor phase back to the liquid phase. In some embodiments, the server cluster further comprises: a heat exchange fluid distribution system in fluidic communication with the heat exchange fluid reservoir and the plurality of membrane heat exchangers.

In some embodiments, the heat exchange fluid distribution system is configured to maintain the heat exchange fluid within the heat exchange fluid distribution system at a hydrostatic pressure within a predetermined range. In some embodiments, the heat exchange fluid reservoir is further configured to cause a second phase change of the volume of the heat exchange fluid in the vapor phase back to the liquid phase. In some embodiments, excess heat removed from the heat exchange fluid reservoir is transferred to a server cluster primary loop of the data center and heat exchange fluid converted back to the liquid phase is transferred back to a primary liquid cooling loop of the data center.

According to another embodiment, a heat sink array can be provided that is configured for cooling a server cluster comprising a plurality of server racks, the heat sink array being configured to be collocated with the server cluster, the heat sink array comprising: a heat exchange fluid reservoir configured to store a supply of a heat exchange fluid in a liquid phase; a plurality of heat exchangers, each of the plurality of heat exchanges configured to be collocated with respective servers of one of the server racks in the server cluster, each of the plurality of heat exchangers comprising an inner volume, a vapor-permeable membrane dimensioned and configured to divide the inner volume of the heat exchanger into at least a first portion and a second portion, a liquid fluid inlet, and a vapor fluid outlet. In some embodiments, the liquid fluid inlet is configured to allow a liquid volume of the heat exchange fluid to be communicated into the first portion of the inner volume of the heat exchanger. In some embodiments, in response to the liquid volume of the heat exchange fluid being exposed to heat from one or more computing entities in one or more server racks of the server cluster collocated with the heat exchanger, at least a portion of the liquid volume of the heat exchange fluid phase changes into a vapor volume of the heat exchange fluid. In some embodiments, the vapor-permeable membrane is configured to allow heat exchange fluid in a vapor phase to be communicated therethrough from the first portion of the inner volume of the heat exchanger to the second portion of the inner volume of the heat exchanger and disallow heat exchange fluid in a liquid phase to be communicated therethrough from the first portion of the inner volume of the heat exchanger to the second portion of the inner volume of the heat exchanger. In some embodiments, the vapor outlet is configured to allow communication of some or all of the vapor volume of the heat exchange fluid to be communicated out of the heat exchanger following the communication of vapor volume of the heat exchange fluid through the vapor-permeable membrane and into the second portion of the inner volume of the heat exchange fluid following the phase change.

According to another embodiment, a heat exchanger device can be provided that comprises: a heat exchange fluid reservoir configured to store a replenishing supply of a heat exchange fluid in a liquid phase; a heat exchanger in fluidic communication with the heat exchange fluid reservoir, the heat exchanger being configured to receive a liquid volume of the heat exchange fluid, expose the liquid volume of the heat exchange fluid to waste heat from one or more collocated computing devices such that at least some of the liquid volume of the heat exchange fluid undergoes a phase change from a liquid phase to a vapor change, and allow communication of a vapor volume of the heat exchange fluid out of the heat exchanger; and a heat exchange fluid recovery unit in fluidic communication with the heat exchanger, the heat exchange fluid recovery unit being configured to cause a further phase change of the vapor volume of the heat exchange fluid from the vapor phase to the liquid phase. In some embodiments, the heat exchanger comprises a vapor-permeable membrane interposed between a first portion of the inner volume of the heat exchanger and a second portion of the inner volume of the heat exchanger.

In some embodiments, the heat exchanger further comprises: a bottom structure defining a first portion of an inner volume of the heat exchanger, the bottom structure comprising a liquid inlet at least partially defined by an aperture through the bottom structure, the liquid inlet being configured to allow the liquid volume of the heat exchange fluid to be communicated from the heat exchange fluid reservoir into the first portion of the inner volume of the heat exchanger. In some embodiments, the heat exchanger further comprises: a top structure defining a second portion of the inner volume of the heat exchanger, the top structure comprising a vapor outlet at least partially defined by an aperture through the top structure, the vapor outlet being configured to allow a volume of the heat exchange fluid in a fluid phase to be communicated out of the second portion of the inner volume of the heat exchanger.

In some embodiments, a portion of a first surface of the vapor-permeable membrane is sealably joined to an inside surface of the bottom structure and a portion of a second surface of the vapor-permeable membrane is sealably joined to an inside surface of the top structure. In some embodiments, the bottom structure of the heat exchanger is configured to allow said exposure of the liquid volume of the heat exchange fluid to said waste heat from the one or more collocated computing devices. In some embodiments, the vapor outlet is configured to allow communication of some or all of the vapor volume of the heat exchange fluid to be communicated out of the heat exchange following the communication of vapor volume of the heat exchange fluid through the vapor-permeable membrane and into the second portion of the inner volume of the heat exchange fluid following the phase change. In some embodiments, the vapor-permeable membrane is configured to prevent communication therethrough of the heat exchange fluid in the liquid phase, thereby protecting said heat-generating component from liquid-related damage. In some embodiments, the heat exchanger device is configured to efficiently dissipate said waste heat generated by the one or more collocated computing devices, thereby increasing an overall thermal performance of said one or more collocated computing devices.

All publications referred to or cited herein are incorporated by reference in their entirety, including all FIGS. and tables, to the extent they are not inconsistent with the explicit teachings of this specification. It should be understood that the examples and embodiments described herein are for illustrative purposes only and that various modifications or changes in light thereof will be suggested to persons skilled in the art and are to be included within the spirit and purview of this application.

What is claimed is:

1. A membrane heat sink configured to absorb excess heat emitted by a collocated computing device, the membrane heat sink comprising:
a liquid region comprising an inlet port configured to communicate a liquid phase heat exchange fluid into the liquid region;
a vapor region comprising an outlet port configured to communicate a vapor phase heat exchange fluid out of the membrane heat sink; and
a vapor-permeable membrane disposed between the liquid region and the vapor region, wherein
the vapor-permeable membrane is configured to allow communication therethrough of the vapor phase heat exchange fluid and disallow communication therethrough of the liquid phase heat exchange fluid,
a rate of communication of the vapor phase heat exchange fluid through the outlet port and out of the vapor region of the membrane heat sink is based upon a rate of communication of the vapor phase heat exchange fluid through the vapor-permeable membrane from the liquid region to the vapor region,
a rate of communication of the liquid phase heat exchange fluid through the inlet port and into the liquid region is based on the rate of communication of the vapor phase heat exchange fluid through vapor-permeable membrane from the liquid region to the vapor region,
the rate of communication of the vapor phase heat exchange fluid through the vapor-permeable membrane from the liquid region into the vapor region is based on a rate at which the liquid phase heat exchange fluid undergoes the phase change to the vapor phase heat exchange fluid, and
the rate at which the liquid phase heat exchange fluid undergoes the phase change to the vapor phase heat exchange fluid is based upon a quantity of the excess heat absorbed by the liquid phase heat exchange fluid.

2. The membrane heat sink of claim 1, wherein the membrane heat sink is further configured, during a first time, to absorb a first quantity of excess heat emitted by the collocated computing device, causing the liquid phase heat exchange fluid in the liquid region to undergo a phase change to the vapor phase heat exchange fluid at a first rate.

3. The membrane heat sink of claim 2, wherein the volume of the liquid phase heat exchange fluid that undergoes the phase change to the vapor phase heat exchange fluid during the first time is based upon a first quantity of the excess heat absorbed by the liquid phase heat exchange fluid during the first time.

4. The membrane heat sink of claim 3, wherein the membrane heat sink is further configured, during a second time, to absorb a second quantity of excess heat emitted by the collocated computing device, causing the liquid phase heat exchange fluid in the liquid region to undergo the phase change to the vapor phase heat exchange fluid at a second rate.

5. The membrane heat sink of claim 4, wherein the volume of the liquid phase heat exchange fluid that undergoes the phase change to the vapor phase heat exchange fluid during the second tie is based upon a second quantity of the excess heat absorbed by the liquid phase heat exchange fluid during the second time.

6. The membrane heat sink of claim 1, wherein the liquid phase heat exchange fluid comprises one or more of: water, a fluorocarbon, or a hydrofluorocarbon.

7. The membrane heat sink of claim 1, wherein the vapor-permeable membrane is microporous or nanoporous.

8. A membrane heat sink device comprising:
a first membrane heat sink configured to be collocated during a time period with a first computing device emitting a first quantity of excess heat during the time period, the first membrane heat sink comprising a first liquid region and a first vapor region, the first liquid region being separated from the first vapor region by a first vapor-permeable membrane, the first liquid region comprising a first inlet configured to communicate a first volume of a liquid phase heat exchange fluid into the first liquid region during the time period,
wherein the first membrane heat sink is configured to communicate a second quantity of excess heat from the first computing device into the first liquid region, the second quantity of excess heat being correlated with the first quantity of excess heat emitted from the first computing device during the time period,
wherein the first volume of the liquid phase heat exchange fluid is configured to absorb the second quantity of excess heat communicated into the first liquid region during the time period such that at least a portion of the first volume of the liquid phase heat exchange fluid undergoes a phase change to a first volume of a vapor phase heat exchange fluid,
wherein a quantity of the portion of the first volume of the liquid phase heat exchange fluid that undergoes the phase change is based on the second quantity of excess heat absorbed by the first volume of the liquid phase heat exchange fluid during the time period,
wherein the first vapor-permeable membrane is configured to allow communication of the first portion of the vapor phase heat exchange fluid from the first liquid region, through the first vapor-permeable membrane, and into the first vapor region,
wherein the first vapor region comprises a first outlet configured to communicate the first volume of the vapor phase heat exchange fluid out of the first vapor region of the first membrane heat sink during the time period, and
wherein the first volume of the vapor phase heat exchange fluid communicated out of the first vapor region of the first membrane heat sink via the first outlet during the time period controls the first volume of the liquid phase heat exchange fluid communicated into the first liquid region of the first membrane heat sink via the first inlet port during the time period.

9. The membrane heat sink device of claim 8, further comprising:
a second membrane heat sink configured to be collocated during the time period with a second computing device emitting a third quantity of excess heat during the time period, the second membrane heat sink comprising a second liquid region and a second vapor region, the second liquid region being separated from the second vapor region by a second vapor-permeable membrane, the second liquid region comprising a second inlet configured to communicate a second volume of the liquid phase heat exchange fluid into the second liquid region during the time period,
wherein the second membrane heat sink is configured to communicate a fourth quantity of excess heat from the second computing device into the second liquid region, the fourth quantity of excess heat being correlated with the third quantity of excess heat emitted from the second computing device during the time period,
wherein the second volume of the liquid phase heat exchange fluid is configured to absorb the fourth quantity of excess heat communicated into the second liquid region during the time period such that at least a portion of the second volume of the liquid phase heat exchange fluid undergoes the phase change to a second volume of the vapor phase heat exchange fluid,
wherein a quantity of the portion of the second volume of the liquid phase heat exchange fluid that undergoes the phase change is based on the fourth quantity of excess heat absorbed by the second volume of the liquid phase heat exchange fluid during the time period,
wherein the second vapor-permeable membrane is configured to allow communication of the second portion of the vapor phase heat exchange fluid from the second liquid region, through the second vapor-permeable membrane, and into the second vapor region,
wherein the second vapor region comprises a second outlet configured to communicate the second volume of the vapor phase heat exchange fluid out of the second vapor region of the second membrane heat sink during the time period, and
wherein the second volume of the vapor phase heat exchange fluid communicated out of the second vapor region of the second membrane heat sink via the second outlet during the time period controls the second volume of the liquid phase heat exchange fluid communicated into the second liquid region of the second membrane heat sink via the second inlet port during the time period.

10. The membrane heat sink device of claim 9, further comprising:
a liquid phase heat exchange fluid reservoir configured to store a replenishing supply of the liquid phase heat exchange fluid, configured to communicate the first volume of the liquid phase heat exchange fluid into the first liquid region within the first membrane heat sink during the time period, and configured to communicate the second volume of the liquid phase heat exchange fluid into the second liquid region within the second membrane heat sink during the time period.

11. The membrane heat sink device of claim 9, further comprising:
a vapor phase heat exchange fluid recovery unit configured to cause a second phase change of the first and second volumes of the vapor phase heat exchange fluid back to liquid phase heat exchange fluid.

12. The membrane heat sink device of claim 9, further comprising:
a liquid phase heat exchange fluid distribution system in fluidic communication with the liquid phase heat exchange fluid reservoir, the first membrane heat sink, and the second membrane heat sink.

13. The membrane heat sink device of claim 12, wherein the liquid phase heat exchange fluid distribution system is configured to maintain the liquid phase heat exchange fluid within the liquid phase heat exchange fluid distribution system at a hydrostatic pressure within a predetermined range.

14. The membrane heat sink device of claim 9, wherein the liquid phase heat exchange fluid comprises one or more of: water, a fluorocarbon, or a hydrofluorocarbon.

15. The membrane heat sink device of claim 9, wherein the vapor-permeable membrane is microporous or nanoporous.

16. A method comprising:
collocating a membrane heat sink with a computing device, the computing device being configured to emit heat energy, the membrane heat sink being configured to absorb heat energy emitted from the computing device, the membrane heat sink comprising a liquid region comprising an inlet port configured to communicate a liquid phase heat exchange fluid into the liquid region, the membrane heat sink further comprising a vapor region comprising an outlet port configured to communicate a vapor phase heat exchange fluid out of the membrane heat sink, the membrane heat sink further comprising a vapor-permeable membrane disposed between the liquid region and the vapor region, the vapor-permeable membrane is further configured to allow communication therethrough of the vapor phase heat exchange fluid and disallow communication therethrough of the liquid phase heat exchange fluid;
communicating a volume of the liquid phase heat exchange fluid into the liquid region of the membrane heat sink;
allowing communication of the portion of heat energy emitted from the computing device collocated with the membrane heat sink into the liquid region, thereby allowing absorption, of at least a portion of the heat energy communicated into the liquid region, into the liquid phase heat exchange fluid being maintained within in the liquid region;
controlling a rate of communication of the vapor phase heat exchange fluid through the outlet port and out of the vapor region of the membrane heat sink based upon a rate of communication of the vapor phase heat exchange fluid through the vapor-permeable membrane from the liquid region to the vapor region;
controlling a rate of communication of the liquid phase heat exchange fluid through the inlet port and into the liquid region based on the rate of communication of the vapor phase heat exchange fluid through vapor-permeable membrane from the liquid region to the vapor region, the rate of vapor phase heat exchange fluid through the vapor-permeable membrane being based on a rate at which the liquid phase heat exchange fluid undergoes the phase change to the vapor phase heat exchange fluid, the rate of phase change of the vapor phase heat exchange fluid being based upon a quantity of the excess heat absorbed by the liquid phase heat exchange fluid;
absorbing, during a first time, a first quantity of excess heat emitted by the collocated computing device, causing the liquid phase heat exchange fluid in the liquid region to undergo a phase change to the vapor phase heat exchange fluid at a first rate; and
absorbing, during a second time, a second quantity of excess heat emitted by the collocated computing device, causing the liquid phase heat exchange fluid in the liquid region to undergo the phase change to the vapor phase heat exchange fluid at a second rate.

17. The method of claim 16, further comprising:
providing a liquid phase heat exchange fluid reservoir configured to store a replenishing supply of the liquid phase heat exchange fluid, the liquid phase heat exchange fluid reservoir being configured to communicate the first volume of the liquid phase heat exchange fluid into the first liquid region within the first membrane heat sink during the time period and further configured to communicate the second volume of the liquid phase heat exchange fluid into the second liquid region within the second membrane heat sink during the time period.

18. The method of claim 16, further comprising
providing a vapor phase heat exchange fluid recovery unit configured to cause a second phase change of the first and second volumes of the vapor phase heat exchange fluid back to liquid phase heat exchange fluid.

19. The method of claim 16, further comprising:
providing a liquid phase heat exchange fluid distribution system, the liquid phase heat exchange fluid distribution system being in fluidic communication with the liquid phase heat exchange fluid reservoir, the first membrane heat sink, and the second membrane heat sink.

20. The method of claim 19, wherein the liquid phase heat exchange fluid distribution system is configured to maintain the liquid phase heat exchange fluid within the liquid phase heat exchange fluid distribution system at a hydrostatic pressure within a predetermined range.
